(19) United States
(12) Patent Application Publication
(10) Pub. No.: US 2026/0323842 A1
(43) Pub. Date: Oct. 15, 2026

(54) CONNECTION STRUCTURE MANUFACTURING METHOD, AND CONNECTION STRUCTURE

(71) Applicant: DEXERIALS CORPORATION, Shimotsuke-shi, Tochigi (JP)

(72) Inventors: Mitsuhiro KARAKITA, Shimotsuke-shi, Tochigi (JP); Kazuhisa AOKI, Shimotsuke-shi, Tochigi (JP); Naoki HAYASHI, Shimotsuke-shi, Tochigi (JP); Hideaki OKUMIYA, Shimotsuke-shi, Tochigi (JP); Hirokazu MASUBUCHI, Shimotsuke-shi, Tochigi (JP); Hiromu YANAGIYA, Shimotsuke-shi, Tochigi (JP)

(73) Assignee: DEXERIALS CORPORATION, Shimotsuke-shi, Tochigi (JP)

(21) Appl. No.: 19/484,916

(22) PCT Filed: May 2, 2024
(86) PCT No.: PCT/JP2024/016883

§ 371 Date: Nov. 17, 2025

(30) Foreign Application Priority Data
May 23, 2023 (JP) 2023-084414
Mar. 27, 2024 (JP) 2024-050937

(51) Int. Cl. H05K 3/3494; H05K 1/181; H05K 3/3465

(52) U.S. Cl. CPC H05K 3/3494; H05K 1/181; H05K 3/3465

(57) ABSTRACT

A connection structure production method includes: disposing a surface mount device including a plurality of terminal rows on a wiring board, interposing a film-shaped solder connection material having rectangular portions corresponding to each of the terminal rows; and joining the surface mount device to the wiring board. A relative standard deviation of a solder thickness between a terminal of the surface mount device and a terminal of the wiring board after the joining is preferably less than 25%.

### TECHNICAL FIELD

The present art relates to a production method of a connection structure that connects, for example, surface mount devices using solder particles, and to the connection structure. The present application claims priority to Japanese Patent Application No. 2023-084414, which was filed in Japan on May 23, 2023 and to Japanese Patent Application No. 2024-050937, which was filed in Japan on Mar. 27, 2024, and contents of these applications are incorporated into the present application by reference thereto.

### BACKGROUND ART

Mounting of surface mount devices (SMD: surface mount device) onto rigid or flexible substrates is generally performed by printing or temporarily attaching solder paste or film to the substrate, placing the surface mount devices on top of it, and then mounting in a reflow step (see, for example, Patent Documents 1 to 3).

In the art taught in Patent Documents 1 to 3, when a surface mount device having a plurality of terminal rows is mounted, some of the solder particles tend to be disposed between the terminal rows, making it difficult to efficiently dispose the solder particles on the electrodes (lines). This can cause short circuits (bridges) between adjacent terminals, making it difficult to achieve high reliability in electrical continuity.

### PRIOR ART DOCUMENTS

### Patent Documents

Patent Document 1: JP 2017-041442 A
Patent Document 2: JP 2016-219808 A
Patent Document 3: WO 2008/023452

### SUMMARY OF INVENTION

### Problem to be Solved by Invention

The present art solves the foregoing problems and provides a connection structure production method that can efficiently move solder particles onto an electrode and obtain highly reliable conductivity, and provides a connection structure.

### Means for Solving Problem

As a result of extensive research, the present inventors have found that the following connection structure production method and connection structure can achieve the above object, and have completed the present art.

[1]

A connection structure production method, having:
a disposing step for disposing a surface mount device having a plurality of terminal rows on a wiring board, interposing a film-shaped solder connection material having rectangular portions corresponding to each of the terminal rows; and
a joining step for joining the surface mount device to the wiring board.

[2]

The connection structure production method according to [1], wherein a relative standard deviation of a solder thickness between terminals of the surface mount device and terminals of the wiring board after the joining step is less than 25%.

[3]

The connection structure production method according to [1] or [2], wherein the surface mount device includes a first terminal row and a second terminal row disposed in parallel, and
in the disposing step, a first film-shaped solder connection material corresponding to the first terminal row and a second film-shaped solder connection material corresponding to the second terminal row are disposed, and a distance between a rectangular portion of the first film-shaped solder connection material and a rectangular portion of the second film-shaped solder connection material is set to 0 mm or more.

[4]

The connection structure production method according to [3], wherein the surface mount device has a first terminal row and a second terminal row disposed in parallel, and in the disposing step, a width W of the rectangular portion of the first film-shaped solder connecting material and a width W of the rectangular portion of the second film-shaped solder connecting material satisfy the following formula (1).

W≤(2L+S)/2 (1)

In the above formula (1), L is a length of the terminals in the first terminal row and the second terminal row, and S is the distance between the first terminal row and the second terminal row.

[5]

The connection structure production method according to [1] or [2], wherein the surface mount device is bonded to the wiring board without load using a reflow furnace in the joining step.

[6]

The connection structure production method according to [1] or [2], wherein a pitch of the terminal rows of the surface mount device and the wiring board is 0.1 mm to 0.4 mm.

[7]

The connection structure production method according to [1] or [2], wherein content of solder particles in the film-shaped solder connection material is 10% by volume to 60% by volume relative to a terminal row pitch of 0.1 mm to 0.4 mm on the surface mount device and the wiring board.

[8]

The connection structure production method according to [1] or [2], wherein the surface mount device includes a first terminal row and a second terminal row disposed in parallel,
in the disposing step, a first film-shaped solder connection material corresponding to the first terminal row and a second film-shaped solder connection material corresponding to the second terminal row are disposed, and
an amount of protrusion of a rectangular portion of the first film-shaped solder connection material from the first terminal row in the width direction is 50% or less of a terminal length of the first terminal row, and an amount of protrusion of a rectangular portion of the second film-shaped solder connection material from the second terminal row in the width direction is 50% or less of a terminal length of the second terminal row.

[9]

The connection structure production method according to [1] or [2], wherein the surface mount device includes a first terminal row and a second terminal row disposed in parallel and a third terminal row and a fourth terminal row disposed in parallel, perpendicular to the first terminal row and the second terminal row, and
an amount of protrusion in a width direction of a rectangular portion corresponding to each of the first terminal row, the second terminal row, the third terminal row, and the fourth terminal row from the terminal row is 50% or less of a terminal length of the each of corresponding first terminal row, second terminal row, third terminal row, and fourth terminal row.

[10]

A connection structure including: a surface mount device including a plurality of terminal rows; a wiring board; and a cured film of a film-shaped solder connection material provided for each of the terminal rows, joining the surface mount device and the wiring board, and having rectangular portions corresponding to each of the terminal rows.

[11]

The connection structure according to [10], wherein a relative standard deviation of a solder thickness between terminals of the surface mount device and terminals of the wiring board is less than 25%.

[12]

The connection structure according to [10] or [11], wherein a pitch of the terminal rows of the surface mount device and the wiring board is 0.1 mm to 0.4 mm.

[13]

The connection structure according to [10] or [11], wherein the surface mount device includes a first terminal row and a second terminal row disposed in parallel, and
an amount of protrusion of a rectangular portion of the first film-shaped solder connection material from the first terminal row in the width direction is 50% or less of a terminal length of the first terminal row, and an amount of protrusion of a rectangular portion of the second film-shaped solder connection material from the second terminal row in the width direction is 50% or less of a terminal length of the second terminal row.

[14]

The connection structure according to [10] or [11], wherein the surface mount device includes a first terminal row and a second terminal row disposed in parallel and a third terminal row and a fourth terminal row disposed in parallel, perpendicular to the first terminal row and the second terminal row, and
an amount of protrusion in a width direction of a rectangular portion corresponding to each of the first terminal row, the second terminal row, the third terminal row, and the fourth terminal row from the terminal row is 50% or less of a terminal length of each of the corresponding first terminal row, second terminal row, third terminal row, and fourth terminal row.

### Effect of Invention

According to the present art, solder particles can be efficiently moved onto the electrodes, and highly reliable conductivity can be obtained.

### BRIEF DESCRIPTION OF DRAWINGS

FIG. 1 is a plan view schematically illustrating a state in which a solder connection film is provided on first and second parallel terminal rows of a wiring board.

FIG. 2 is a cross-sectional view schematically illustrating a state in which a solder connection film is provided on a first terminal row of a wiring board.

FIG. 3 is a cross-sectional view schematically illustrating a state in which a first terminal row of a wiring board and a first terminal row of a surface mount device are aligned.

FIG. 4 is a cross-sectional view schematically illustrating a state in which a wiring board and a surface mount device are heated in a reflow furnace.

FIG. 5 is a plan view schematically illustrating one example of a wiring board.

FIG. 6(A) is a plan view schematically illustrating an example of a metal mask as an embodiment, and FIG. 6(B) is a plan view schematically illustrating one example of a solder paste film printed using the metal mask illustrated in FIG. 6(A).

FIG. 7(A) is a plan view schematically illustrating one example of a metal mask as a comparative example, and FIG. 7(B) is a plan view schematically illustrating one example of a solder paste film printed using the metal mask illustrated in FIG. 7(A).

FIG. 8(A) is a plan view schematically illustrating one example of a metal mask as a comparative example, and FIG. 8(B) is a plan view schematically illustrating one example of a solder paste film printed using the metal mask illustrated in FIG. 8(A).

FIG. 9 is a cross-sectional view illustrating an example of a plug and a receptacle in a vertical fitting type connector in a width direction.

FIG. 10 is a cross-sectional view schematically illustrating a length direction of a connection structure in which a plug of a connector and a wiring board are connected.

FIG. 11 is a cross-sectional view schematically illustrating a width direction of a connection structure in which a plug of a connector and a wiring board are connected.

FIG. 12(A) is a photograph showing a state in which a solder connection film is temporarily pasted on a printed wiring board for Example 1, FIG. 12(B) is a photograph showing a state in which a connector is mounted on a printed circuit board for Example 1, and FIG. 12(C) is an X-ray photograph showing the connection structure after reflow for Example 1.

FIG. 13(A) is a photograph showing a state in which a solder connection film is temporarily pasted on a printed wiring board for Comparative Example 1, FIG. 13(B) is a photograph showing a state in which a connector is mounted on a printed circuit board for Comparative Example 1, and FIG. 13(C) is an X-ray photograph showing a connection structure after reflow for Comparative Example 1.

FIG. 14 is a photograph showing a sample after reflow for Example 13.

FIG. 15 is a photograph showing a sample after reflow for Comparative Example 6.

FIG. 16 is an X-ray photograph showing a sample after reflow for Example 15.

FIG. 17 is an X-ray photograph showing a sample after reflow for Example 8.

FIG. 18(A1) is a photograph showing a state in which an anisotropic conductive film of a predetermined shape has been temporarily bonded on a wiring board for a plug connector as Comparative Example 9, FIG. 18(A2) is a plan view schematically illustrating the shape of the anisotropic conductive film, FIG. 18(B) is a photograph showing a state in which a plug connector has been reflow mounted on a wiring board for a plug connector, and FIG. 18(C) is an X-ray photograph showing a plug connector structure after mounting.

FIG. 19(A1) is a photograph showing a state in which an anisotropic conductive film of a predetermined shape has been temporarily bonded on a wiring board for a plug connector as Example 16, FIG. 19(A2) is a plan view schematically illustrating the shape of the anisotropic conductive film, FIG. 19(B) is a photograph showing a state in which a plug connector has been reflow mounted on a wiring board for a plug connector, and FIG. 19(C) is an X-ray photograph showing a plug connector structure after mounting.

FIG. 20(A1) is a photograph showing a state in which an anisotropic conductive film of a predetermined shape has been temporarily bonded on a wiring board for a plug connector as Example 17, FIG. 20(A2) is a plan view schematically illustrating the shape of the anisotropic conductive film, FIG. 20(B) is a photograph showing a state in which a plug connector has been reflow mounted on a wiring board for a plug connector, and FIG. 20(C) is an X-ray photograph showing a plug connector structure after mounting.

FIG. 21(A1) is a photograph showing a state in which an anisotropic conductive film of a predetermined shape has been temporarily bonded on a wiring board for a plug connector as Comparative Example 18, FIG. 21(A2) is a plan view schematically illustrating the shape of the anisotropic conductive film, FIG. 21(B) is a photograph showing a state in which a plug connector has been reflow mounted on a wiring board for a plug connector, and FIG. 21(C) is an X-ray photograph showing a plug connector structure after mounting.

FIG. 22(A1) is a photograph showing a state in which an anisotropic conductive film of a predetermined shape is temporarily bonded to a wiring board for a receptacle connector as Comparative Example 10, FIG. 22(A2) is a plan view schematically illustrating the shape of the anisotropic conductive film, FIG. 22(B) is a photograph showing a state in which the receptacle connector is reflow mounted on the wiring board for the receptacle connector, and FIG. 22(C) is an X-ray photograph showing a receptacle connector structure after mounting.

FIG. 23(A1) is a photograph showing a state in which an anisotropic conductive film of a predetermined shape is temporarily bonded to a wiring board for a receptacle connector as Comparative Example 19, FIG. 23(A2) is a plan view schematically illustrating the shape of the anisotropic conductive film, FIG. 23(B) is a photograph showing a state in which the receptacle connector is reflow mounted on the wiring board for the receptacle connector, and FIG. 23(C) is an X-ray photograph showing a receptacle connector structure after mounting.

FIG. 24(A1) is a photograph showing a state in which an anisotropic conductive film of a predetermined shape is temporarily bonded to a wiring board for a receptacle connector as Comparative Example 20, FIG. 24(A2) is a plan view schematically illustrating the shape of the anisotropic conductive film, FIG. 24(B) is a photograph showing a state in which the receptacle connector is reflow mounted on the wiring board for the receptacle connector, and FIG. 24(C) is an X-ray photograph showing a receptacle connector structure after mounting.

### EMBODIMENTS OF INVENTION

Embodiments of the present art will be described below in detail in the following order with reference to the drawings.
1. Connection structure production method and connection structure
2. Solder connection film
3. First example
4. Second example
5. Third example
6. Fourth example

### 1. Connection Structure Production Method and Connection Structure

The connection structure production method according to the present embodiment has: a disposing step for disposing a surface mount device having a plurality of terminal rows on a wiring board, interposing a film-like solder connection material having a rectangular portion whose length direction is a row direction of the terminal rows; and a joining step for joining the surface mount device to the wiring board. Here, when the surface mount device has a first terminal row and a second terminal row disposed in parallel, it is preferable that an amount of protrusion of a solder connection film of the first terminal row or the second terminal row disposed between the first terminal row and the second terminal row is 50% or less of a terminal length in a direction perpendicular to the row direction of the first terminal row or the second terminal row. Furthermore, when the surface mount device includes a first terminal row and a second terminal row disposed in parallel and a third terminal row and a fourth terminal row disposed in parallel, perpendicular to the first terminal row and the second terminal row, it is preferable that the amount of protrusion of the solder connection film of the first terminal row, the second terminal row, the third terminal row or the fourth terminal row disposed between the first terminal row and the second terminal row is 50% or less of the terminal length in the direction perpendicular to the row direction of the first terminal row, the second terminal row, the third terminal row, or the fourth terminal row. This can prevent solder particles from remaining unaggregated between the first terminal row and the second terminal row.

The connection structure according to the present embodiment includes: a surface mount device including a plurality of terminal rows; a wiring board; and a cured film of a film-shaped solder connection material provided for each of the terminal rows, joining the surface mount device and the wiring board, and having a rectangular portion whose length direction is, for each terminal row, a row direction of the terminal row. Here, when the surface mount device has a first terminal row and a second terminal row disposed in parallel, it is preferable that an amount of protrusion of a cured solder connection film of the first terminal row or the second terminal row disposed between the first terminal row and the second terminal row is 50% or less of a terminal length in a direction perpendicular to the row direction of the first terminal row or the second terminal row. Furthermore, when the surface mount device includes a first terminal row and a second terminal row disposed in parallel and a third terminal row and a fourth terminal row disposed in parallel, perpendicular to the first terminal row and the second terminal row, it is preferable that the amount of protrusion of the cured solder connection film of the first terminal row, the second terminal row, the third terminal row or the fourth terminal row disposed between the first terminal row and the second terminal row is 50% or less of the terminal length in the direction perpendicular to the row direction of the first terminal row, the second terminal row, the third terminal row, or the fourth terminal row. This can prevent solder particles from remaining unaggregated within the first terminal row to the fourth terminal row.

In the present embodiment, by providing a film-shaped solder connection material having a rectangular portion whose length direction is, for each terminal row, the row direction of the terminal row, movement of solder particles between the terminal rows due to a self-alignment effect is restricted during the joining step. This allows the solder particles to aggregate within a predetermined rectangular portion for a predetermined terminal row, thereby achieving highly reliable electrical conductivity. As will be described later, the film-shaped solder connecting material may be a solder connecting film or a solder paste film on which solder paste is printed.

The film-shaped solder connecting material may be continuous in areas other than the rectangular portions corresponding to the terminal rows. For example, when connecting a connector having a first terminal row and a second terminal row disposed in parallel, a film-shaped solder connecting material may be used in which both longitudinal ends of two parallel rectangular portions are connected by a continuous portion. Such a film-shaped solder connecting material can further improve adhesive strength due to the continuous portions at both ends.

Here, a connection structure refers to an electrical connection between two materials or members. Also, joining refers to joining two materials or members together. Moreover, a terminal row refers to terminals (electrodes) disposed in a predetermined direction at a predetermined interval (pitch). Moreover, a predetermined direction in which the terminals are lined up is called a row direction of the terminal row, and a direction perpendicular to the row direction is called a width direction of the terminal row.

The surface mount device is not particularly limited as long as it has a plurality of terminal rows, and examples thereof include a component having a first terminal row and a second terminal row disposed in parallel, a component having a first terminal row and a second terminal row disposed in parallel and a component having a third terminal row and a fourth terminal row disposed in parallel, perpendicular to the first terminal row and the second terminal row, and the like.

Specific examples of surface mount devices include connectors, IC (Integrated Circuit) and LSI (Large Scale Integration) packages, LEDs (Light Emitting Diodes), switches, and the like. For example, the connector may be an SMT (Surface Mount type) type connector having a first terminal row in which a plurality of pins (lead frames) extending outward on one side of the short side are disposed in the length direction and a second terminal row in which a plurality of pins (lead frames) extending outward on the other side of the short side are disposed in the length direction. Examples of IC packages include surface mount leaded types such as SOP (Small Outline Package) and SOJ (Small Outline J-leaded), which have terminal rows on two opposing sides of a rectangle, QFP (Quad Flat Package) and QFN (Quad Flat No-leaded package), which have terminal rows on four sides of a rectangle, and the like.

The wiring board is not particularly limited as long as it has wiring, and it may be broadly defined as a so-called printed wiring board (PWB) that has electrodes on which surface mount devices can be mounted and may be either a rigid board or a flexible board (FPC: Flexible Printed Circuits). Examples of substrates based on the type of base material include glass substrates, ceramic substrates, plastic substrates, and the like.

An upper limit of the pitch of the terminal rows of the surface mount device and wiring board is preferably 2 mm or less, more preferably 1 mm or less, and even more preferably 0.5 mm or less, and the lower limit of the pitch of the terminal rows is preferably 0.06 mm or more, more preferably 0.08 mm or more, and even more preferably 0.1 mm or more.

An average thickness (height) of the solder between the terminals of the connection structure depends on the electrode area of the wiring board and surface mount device, the solder particle content of the film-shaped solder connection material, and the like, but a lower limit of the thickness is preferably 5 μm or more, more preferably 20 μm or more, and even more preferably 40 μm or more. An upper limit of the thickness is preferably 200 μm or less, more preferably 100 μm or less, and even more preferably 80 μm or less. This makes it possible to withstand stress caused by the difference in linear expansion between the surface mount device and the wiring board due to thermal shock, and to obtain high reliability of electrical continuity.

Furthermore, the relative standard deviation (coefficient of variation, RSD (Relative Standard deviation)) of the thickness (height) of the solder between the terminals after reflow is preferably less than 25%, more preferably 20% or less, and even more preferably 15% or less. High reliability of conduction can be achieved by minimizing variation in thickness (height) of the solder between terminals. Furthermore, the standard deviation (σ) of the thickness (height) and the like of the solder between the terminals of the connection structure depends on the average thickness (height) of the solder between the terminals, but for example, when the average thickness (height) of the solder between the terminals is 5 μm or more and 200 μm, it is preferably 20 μm or less, more preferably 12 μm or less, and even more preferably 10 μm or less. High reliability of conduction can be achieved by minimizing variation in thickness of the solder between terminals.

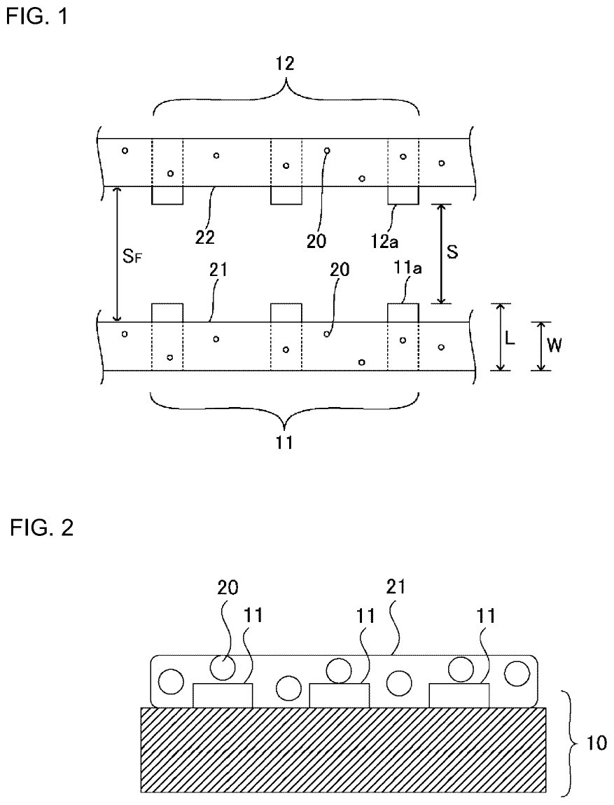

Below, with reference to FIG. 1 to FIG. 4, the following will be described: a step (A) for providing a solder connection film on a plurality of terminal rows of a wiring board, a step (B) for fixing surface mount devices on the solder connection film, and a step (C) for joining the plurality of terminal rows of the wiring board and the plurality of terminal rows of the surface mount devices using a reflow furnace.

### [Step (A)]

FIG. 1 is a plan view illustrating a state in which a solder connection film is provided on each of parallel first terminal row and second terminal row of a wiring board, and FIG. 2 is a cross-sectional view illustrating a state in which a solder connection film is provided on the first terminal row of the wiring board. As illustrated in FIG. 1 and FIG. 2, in step (A), a rectangular first solder connection film 21 and a rectangular second solder connection film 22 containing solder particles 20 and having the row direction of the terminal rows as the length direction are provided on a first terminal row 11 and a second terminal row 12 of a wiring board 10.

Step (A) may be a temporary attachment step in which the first solder connection film 21 and the second solder connection film 22 are attached to the first terminal row 11 and the second terminal row 12 of the wiring board 10, respectively, at low temperature and low pressure, or may be a lamination step in which the first solder connection film 21 and the second solder connection film 22 are laminated to the first terminal row 11 and the second terminal row 12 of the wiring board 10, respectively.

A width W of the first and second solder connecting films 21 and 22 is preferably 50% to 150% of a length L of the terminals 11a and 12a, and more preferably 75% to 125%. This allows the solder particles to aggregate on the terminals of the terminal row, thereby reducing variations in the solder height on the terminals of the terminal row.

Preferably, the first and second solder connection films 21 and 22 are provided aligned with the outer end portions of the first terminal row 11 and the second terminal row 12 in the width direction. In addition, the widthwise protrusion (W−L) of the rectangular portion of the first or second solder connection film disposed between the first terminal row and second terminal row 11 and 12 is preferably 50% or less of the length L of the terminals 11a and 12a, and more preferably 25% or less. This can prevent the solder particles 20 from remaining unaggregated between the first terminal row 11 and the second terminal row 12.

It is preferable that the width W of the first and second solder connecting films 21 and 22 satisfy the following formula (1).

W≤(2L+S)/2 (1)

In the above formula (1), L is a length of the terminals 11a and 12a, and S is a distance between the first terminal row 11 and the second terminal row 12. It is sufficient that there is a boundary between the first solder connecting film 21 and the second solder connecting film 22, and a distance (gap) SF therebetween may be zero.

The distance S between the first terminal row 11 and the second terminal row 12 is preferably 10 mm or less, more preferably 1 mm or less, and even more preferably 0.5 mm or less. Even when the distance S between the first terminal row 11 and the second terminal row 12 is short, it is preferable that there is a boundary between the first solder connection film 21 and the second solder connection film 22, and the distance (gap) SF is preferably 0 mm or more, preferably 0.1 mm or more, and more preferably 0.2 mm or more. The presence of a boundary between the first solder connection film 21 and the second solder connection film 22 makes it possible to restrict the movement of solder particles and reduce variations in the solder height on the terminals of the terminal row.

### [Step (B)]

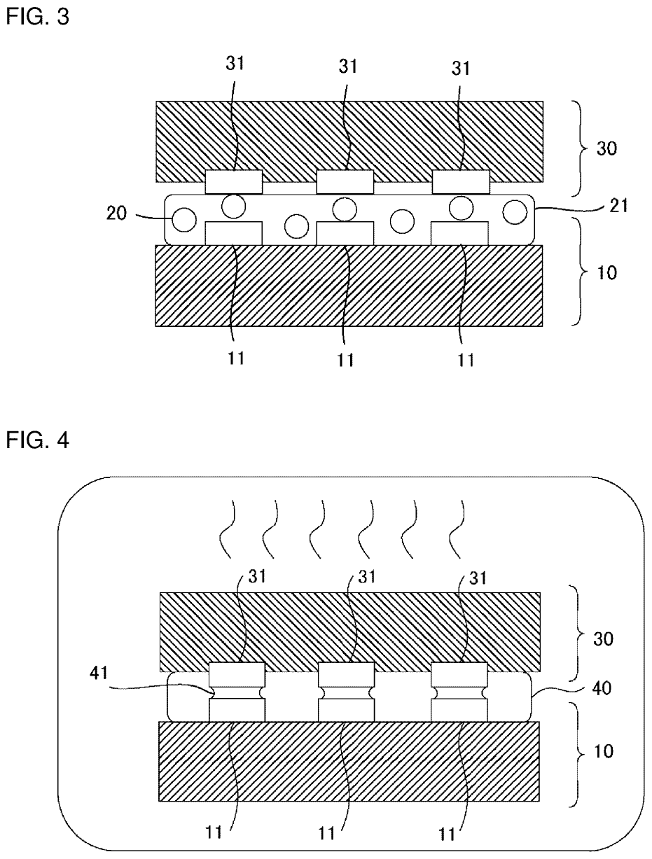

FIG. 3 is a cross-sectional view schematically illustrating a state in which a first terminal row of a wiring board and a first terminal row of a surface mount device are aligned. As illustrated in FIG. 3, in step (B), the first terminal row and second terminal row 11 and 12 of the wiring board 10 are aligned with first terminal row and second terminal row 31 and 32 of the surface mount device 30, and the surface mount device 30 is fixed onto the first solder connection film 21.

In step (B), the first terminal row and second terminal row 11 and 12 and the first terminal row and second terminal row 31 and 32 of the surface mount device 30 are aligned using, for example, a tool. The tool preferably includes a suction mechanism for suctioning the surface mount device. Furthermore, in step (B), temporary pressure bonding may be performed by using the tool to press from the surface mount device 30 side.

### [Step (C)]

FIG. 4 is a cross-sectional view schematically illustrating a state in which a wiring board and a surface mount device are heated in a reflow furnace. As illustrated in FIG. 4, in step (C), a reflow furnace set at a temperature equal to or higher than a melting point of the solder particles 20 is used to join the first terminal row and second terminal row 11 and 12 of the wiring board 10 and the first terminal row and second terminal row 31 and 32 of the surface mount device 30 using solder 41, and the wiring board 10 and the surface mount device 30 are bonded together using a binder 40 of the solder connection film. Here, first and second solder connection films 21 and 22 containing solder particles 20 are provided on the first terminal row and second terminal row 11 and 12 of the wiring board 10, respectively, and thus during reflow, the movement of the solder particles between the terminal rows due to the self-alignment effect is restricted. This allows only the solder particles 20 in the first and second solder connection films 21 and 22 to aggregate with respect to the first terminal row and second terminal row 11 and 12, respectively.

Examples of reflow furnaces include atmospheric pressure reflow, vacuum reflow, atmospheric pressure ovens, and autoclaves (pressure ovens), among which, it is preferable to use vacuum reflow, autoclaves, and the like, which can eliminate air bubbles contained in the joint. The reflow furnace can heat and bond the components without applying mechanical pressure and without load, and thus damage to the wiring board 10 and the surface mount devices 30 can be suppressed. Here, “without load” refers to a state in which no mechanical pressure is applied.

A lower limit of the peak temperature (maximum temperature reached) in the reflow furnace should be above the temperature at which the solder particles melt and above the temperature at which the solder connection film begins to harden, and is preferably 150° C. or higher, more preferably 180° C. or higher, and even more preferably 200° C. or higher. An upper limit of peak temperature in the reflow furnace is preferably 300° C. or less, more preferably 290° C. or less, and even more preferably 280° C. or less. As a result, the first terminal row 11 of the wiring board 10 and the first terminal row 31 of the surface mount device 30 are soldered together. Furthermore, when a thermosetting binder is used for the solder connection film, portions other than solder joint portions within the terminals are bonded by the thermosetting binder. Here, solder joining refers to connecting respective terminals (electrodes) of opposing electronic components by melting solder.

The average thickness (height) T of the solder 41 between the terminals after reflow is based on the electrode area of the wiring board and the surface mount device, the content of solder particles in the solder connection film, and the like, but the lower limit of the thickness is preferably 5 μm or more, more preferably 20 μm or more, and even more preferably 40 μm or more. An upper limit of the thickness T is preferably 200 μm or less, more preferably 100 μm or less, and even more preferably 80 μm or less. This makes it possible to withstand stress caused by the difference in linear expansion between the surface mount device and the wiring board due to thermal shock, and to obtain high reliability of electrical continuity.

Furthermore, the relative standard deviation (coefficient of variation, RSD (Relative Standard deviation)) of the thickness (height) of the solder between the terminals after reflow is preferably less than 25%, more preferably 20% or less, and even more preferably 15% or less. High reliability of conduction can be achieved by minimizing variation in thickness (height) of the solder between terminals. Furthermore, the standard deviation (σ) of the thickness (height) and the like of the solder between the terminals of the connection structure depends on the average thickness (height) of the solder between the terminals, but for example, when the average thickness (height) of the solder between the terminals is 5 μm or more and 200 μm, it is preferably 20 μm or less, more preferably 12 μm or less, and even more preferably 10 μm or less. High reliability of conduction can be achieved by minimizing variation in thickness of the solder 41 between terminals.

According to the connection structure production method described above, by providing a solder connection film for each terminal row, it is possible to limit movement of solder particles between terminal rows due to the self-alignment effect during heating. Therefore, it is possible to aggregate only the solder particles in a predetermined solder connection film for a predetermined terminal array, and high conduction reliability can be obtained.

In the connection structure production method described above, in step (C), a reflow furnace is used to join a plurality of terminal rows of the wiring board and a plurality of terminal rows of the surface mount device, but such is not limited thereto, and for example, joining may be performed using a heating and pressurizing tool within a range that does not prevent the solder particles from aggregating on the terminals.

The solder connection film may be shaped according to the electrode pattern of the wiring board. For example, the solder connection film may have a substantially rectangular first shaped portion corresponding to a predetermined terminal row, a second shaped portion connected to one end of the first shaped portion and corresponding to an electrode at one end of the predetermined terminal row, and a third shaped portion connected to the other end of the first shaped portion and corresponding to an electrode at the other end of the predetermined terminal row, and may have a shape that combines from the first shaped portion to the third shaped portion. Furthermore, for example, the solder connection film may have a substantially rectangular first shaped portion corresponding to the first terminal row, a substantially rectangular second shaped portion corresponding to the second terminal row, a third shaped portion connecting one end of the first shaped portion to one end of the second shaped portion and corresponding to a pair of electrodes at one end of the first terminal row and the second terminal row, and a fourth shaped portion connecting the other end of the first shaped portion to the other end of the second shaped portion and corresponding to a pair of electrodes at the other end of the first terminal row and the second terminal row, and may have a shape that combines from the first shaped portion to the fourth shaped portion.

Also, as described above, the distance (gap) between the shaped portions corresponding to adjacent terminal rows is preferably 0 mm or more, preferably 0.1 mm or more, and more preferably 0.2 mm or more. The presence of a boundary between the shapes corresponding to adjacent terminal rows makes it possible to restrict the movement of solder particles and reduce variations in the solder height on the terminals of the terminal rows. A solder connection film having such a shape can be obtained by punching, slitting (slitting), or the like.

### Modifications

In the connection structure production method described above, in step (A), a solder connection film is provided on the terminal row, but this is not limited to this, and for example, a metal mask (stencil) may be used to print solder paste, and the solder paste film may be provided on the terminal row. The solder paste may be, for example, a solder connection film, which will be described later, with the viscosity reduced by removing a polymer component from the binder formulation.

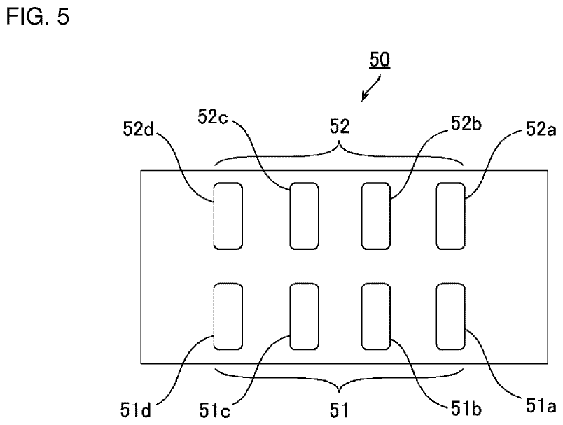

Printing of solder paste using a metal mask will be described below with reference to FIG. 5 to FIG. 8. FIG. 5 is a plan view schematically illustrating one example of a wiring board. As illustrated in FIG. 5, a wiring board 50 includes a first terminal row 51 in which a plurality of terminals 51a, 51b, 51c, and 51d are disposed at predetermined intervals and a second terminal row 52 in which a plurality of terminals 52a, 52b, 52c, and 52d are disposed at predetermined intervals. A row direction of the first terminal row 51 and a row direction of the second terminal row 52 are parallel, and the distance between the first terminal row 51 and the second terminal row 52 is, as described above, preferably 10 mm or less, more preferably 1 mm or less, and even more preferably 0.5 mm or less.

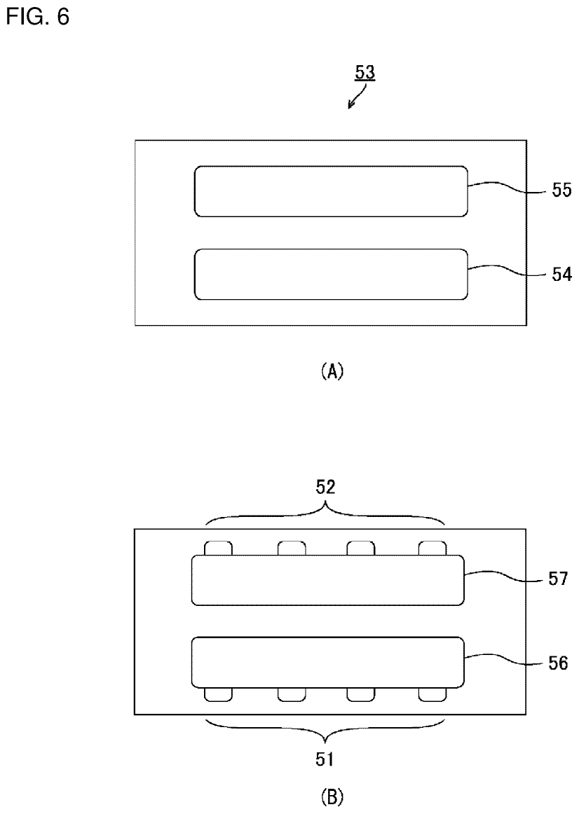

FIG. 6(A) is a plan view schematically illustrating an example of a metal mask as an embodiment, and FIG. 6(B) is a plan view schematically illustrating one example of a solder paste film printed using the metal mask illustrated in FIG. 6(A). A metal mask 53 illustrated in FIG. 6(A) has a first opening 54 corresponding to the first terminal row 51 and a second opening 55 corresponding to the second terminal row 52.

The method of printing solder paste involves aligning and setting the wiring board 50 under the metal mask 53, then moving a squeegee while pressing the metal mask 53 downward from above, applying the solder paste to the predetermined locations through the openings in the metal mask 53, and then removing the set wiring board 50. This allows a solder paste film having the same shape as the opening of the metal mask 53 to be transferred onto the wiring board 50.

As illustrated in FIG. 6(B), on the wiring board 50, a first solder paste film 56 having the same shape as the first opening 54 is provided on the first terminal row 51, and a second solder paste film 57 having the same shape as the second opening 55 is provided on the second terminal row 52, with a gap being provided between the first solder paste film 56 and the second solder paste film 57. This limits movement of solder particles between terminal rows due to a self-alignment effect when heated, allowing only the solder particles in a predetermined solder connection film to aggregate with a predetermined terminal row, resulting in highly reliable conductivity.

Furthermore, the thickness of the solder paste film printed on the wiring board 50, like the solder connection film described later, has a lower limit of preferably 0.6 or more, more preferably 0.8 or more, and even more preferably 0.9 or more relative to the average particle size of the solder particles. Furthermore, an upper limit of the thickness is preferably 3.0 or less, more preferably 2.0 or less, and even more preferably 1.5 or less, based on the average particle diameter of the solder particles. When the ratio of the average particle size of the solder particles to the thickness of the solder paste film is large, there is a risk that printing using a metal mask will become more difficult.

Here, the thickness of the solder paste film refers to the thickness of the binder resin layer only and does not include the particle diameter. The thickness of the film-shaped solder paste may be measured using a known micrometer or digital thickness gauge (for example, MDE-25M, manufactured by Mitutoyo Co., Ltd., minimum display 0.0001 mm) that can measure thicknesses of 1 μm or less, preferably 0.1 μm or less. The film thickness can be determined by measuring at 10 or more locations and averaging the results.

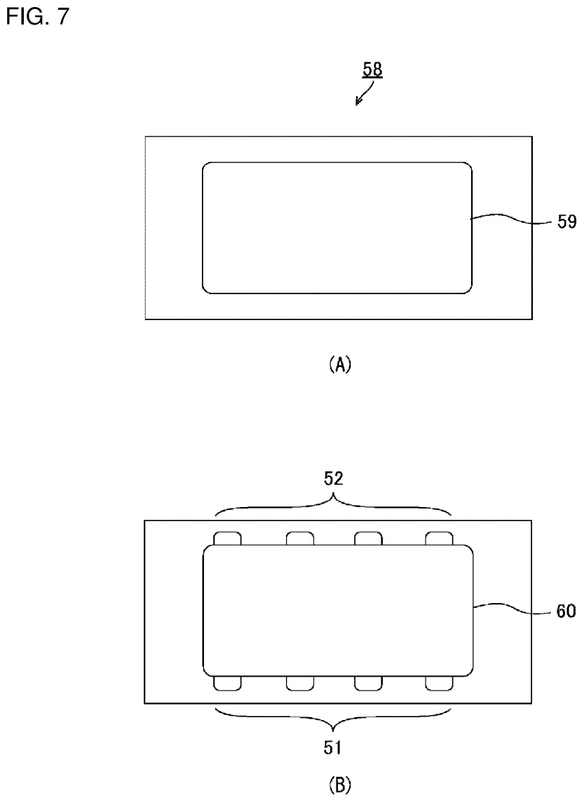

FIG. 7(A) is a plan view schematically illustrating one example of a metal mask as a comparative example, and FIG. 7(B) is a plan view schematically illustrating one example of a solder paste film printed using the metal mask illustrated in FIG. 7(A). A metal mask 58 illustrated in FIG. 7(A) has an opening 59 corresponding to both the first terminal row 51 and the second terminal row 52.

When a solder paste film having the same shape as the opening of the metal mask 58 is transferred to the wiring board 50, as illustrated in FIG. 7(B), a solder paste film 60 having the same shape as the opening 59 is provided on the first terminal row 51 and the second terminal row 52 on the wiring board 50. In this case, the solder particles move between the terminal rows during heating, causing the solder particles to be distributed unevenly, which increases the degree of variation in the solder thickness (height) between the upper and lower terminals, making it difficult to achieve highly reliable conductivity.

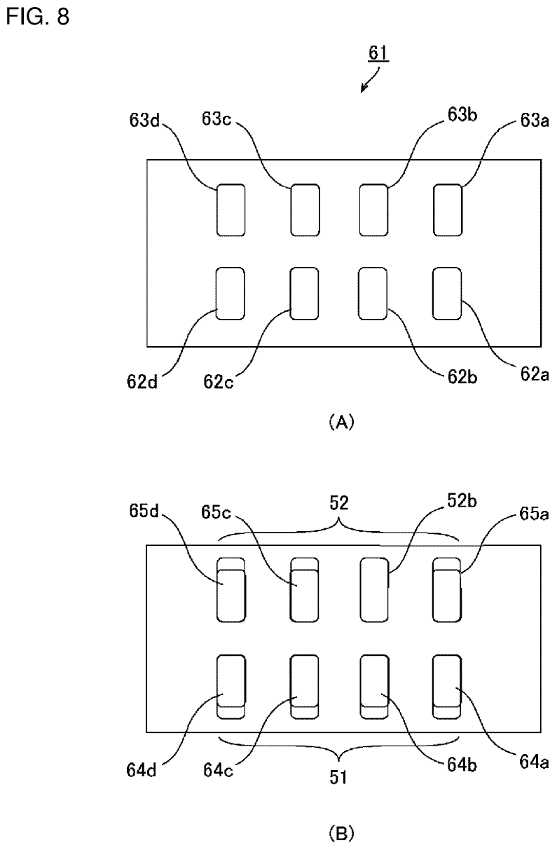

FIG. 8(A) is a plan view schematically illustrating one example of a metal mask as a comparative example, and FIG. 8(B) is a plan view schematically illustrating one example of a solder paste film printed using the metal mask illustrated in FIG. 8(A). The metal mask 61 illustrated in FIG. 8(A) has openings 62a, 62b, 62c, and 62d that respectively correspond to the terminals of the first terminal row 51, and openings 63a, 63b, 63c, and 63d that respectively correspond to the terminals of the second terminal row 52.

When a solder paste film of the same shape as the opening of the metal mask 61 is transferred to the wiring board 50, as illustrated in FIG. 8(b), solder paste films 64a, 64b, 64c, 64d, 65a, 65b, 65c, 65d having the same shapes as the openings 62a, 62b, 62c, 62d, 63a, 63b, 63c, 63d are provided on the wiring board 50 on the terminals 51a, 51b, 51c, 51d of the first terminal row 51 and the terminals 52a, 52b, 52c, 52d of the second terminal row 52, respectively. In this case, when the openings in the metal mask become smaller due to finer patterning, the solder paste remains in the openings, and a situation occurs in which the solder paste is not transferred to the wiring board 50, as in the case of terminal 52b illustrated in FIG. 8 (B).

### [Connector Assembly]

In the following, a connector assembly using a vertical mating type connector will be described in detail as a specific example of a surface mount device. The connector is mainly a resin molded product having a mating portion, and may be, for example, a resin molded product having a plurality of electrodes protruding longitudinally (a so-called centipede-type connector) or not having protruding electrodes (a flip-chip-type connector).

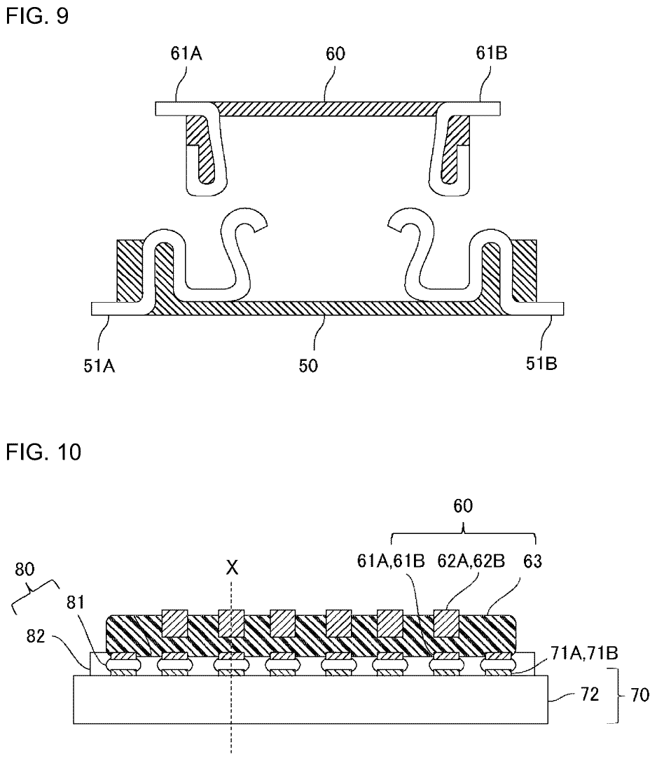

FIG. 9 is a cross-sectional view illustrating an example of a plug and a receptacle in a vertical fitting type connector in a width direction. The example of the connector illustrated in FIG. 9 is composed of a receptacle 70 in which receptacle terminals 71A and 71B are fixed with insulating resin, and a plug 80 in which plug terminals 81A and 81B are fixed using insulating resin. Furthermore, the receptacle terminals 71A and 71B are formed at a predetermined pitch in the length direction of receptacle 70, and the plug terminals 81A and 81B are formed at a predetermined pitch in the length direction of plug 80.

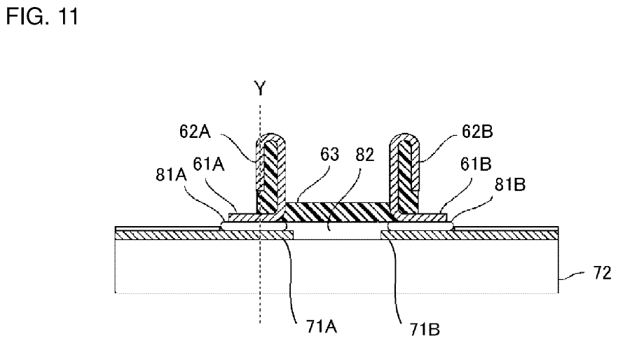

FIG. 10 is a cross-sectional view schematically illustrating a length direction of a connection structure in which a plug of a connector and a wiring board are connected, and FIG. 11 is a cross-sectional view schematically illustrating a width direction of a connection structure in which a plug of a connector and a wiring board are connected. That is, the longitudinal cross-section illustrated in FIG. 10 is a Y cross-section perpendicular to the lateral cross-section illustrated in FIG. 11, and the lateral cross-section illustrated in FIG. 11 is an X cross-section perpendicular to the longitudinal cross-section illustrated in FIG. 10.

As illustrated in FIG. 10 and FIG. 11, the connector assembly includes a plug 80 having plug terminals 81A as a first terminal row and plug terminals 81B as a second terminal row, a wiring board 90 having board terminals 91A and 91B corresponding to the plug terminals 81A and 81B, and an adhesive layer 100 that joins the plug terminals 81A and 81B and the board terminals 91A and 91B using solder 101.

The plug 80 includes plug terminals 81A and 81B, connection pins 82A and 82B formed by bending conductive metal continuous with the plug terminals 81A and 81B, and insulating resin 83 that fixes the plug terminals 81A and 81B and the connection pins 82A and 82B.

Insulating resin 83 is made of, for example, polyamide, LCP (Liquid Crystal Polymer), or the like and fixes the plug terminals 81A and 81B and the connection pins 82A and 82B by, for example, resin molding. Furthermore, leads are formed at respective ends of the plug terminals 81A and 81B, and the plug terminals 81A and 81B form a surface-mounted lead array.

An upper limit of a minimum value of the distance between adjacent terminals (space distance) in the plug terminals 81A and 81B and the board terminals 91A and 91B is preferably 0.8 mm or less, more preferably 0.3 mm or less, and even more preferably 0.2 mm or less. A lower limit of a minimum distance between adjacent terminals in the plug terminals 81A and 81B and the board terminals 91A and 91B is preferably 50 μm or more, more preferably 60 μm or more, and even more preferably 70 μm or more. Furthermore, surfaces of the plug terminals 81A and 81B are preferably gold-plated.

The wiring board 90 has the board terminals 91A and 91B on a base material, which correspond the to plug terminals 81A and 81B. The wiring board 70 can be broadly defined as a so-called printed wiring board (PWB) that has electrodes on which surface mount devices can be mounted and may be either a rigid board or a flexible board (FPC: Flexible Printed Circuits). Examples of substrates based on the type of base material include glass substrates, ceramic substrates, plastic substrates, and the like. Surfaces of the substrate terminals 91A and 91B are preferably plated with gold.

An adhesive layer 100 includes solder 101 for joining the plug terminals 81A and 81B and the board terminals 91A and 91B, and a hardened binder 102. The adhesive layer 80 is formed by curing a solder connection film described below and joins the plug terminals 81A and 81B and the board terminals 91A and 91B using the solder 81 and is formed by hardening a binder of the solder connection film between the plug 80 and the wiring board 90.

### 2. Solder Connection Film

The solder connecting film according to the present embodiment contains a binder, solder particles, and a flux compound. By making the solder connection film in the form of a film, not only can the amount of solder particles be made uniform, but also the film is easy to handle, thereby increasing work efficiency.

A lower limit of the thickness of the solder connection film is preferably 0.6 or more, more preferably 0.8 or more, and even more preferably 0.9 or more, based on the average particle size of the solder particles. Furthermore, an upper limit of the thickness of the solder connection film is preferably 3.0 or less, more preferably 2.0 or less, and even more preferably 1.5 or less, based on the average particle diameter of the solder particles. When the ratio of the average particle size of the solder particles to the thickness of the solder connection film is large, the solder connection film may become more difficult to handle. Here, the thickness of the solder continuous film refers to the thickness of the binder resin layer only and does not include the particle diameter.

The thickness of the solder connection film may be measured using a known micrometer or digital thickness gage that can measure 1 μm or less, preferably 0.1 μm or less (for example, Mitutoyo Co., Ltd.: MDE-25M, minimum display quantity 0.0001 mm). The film thickness can be determined by measuring at 10 or more locations and averaging the results. However, when the film thickness is thinner than the particle diameter, a contact-type thickness measuring device is not suitable, so it is preferable to use a laser displacement meter (for example, Keyence Corporation, spectral interference displacement type SI-T series, or the like).

The binder of the solder connection film may be either thermosetting or thermoplastic but is preferably thermosetting so that it can be melted and hardened by temperature control in a reflow process. The thermosetting binder (insulating binder) will be described below.

### [Thermosetting Binder]

The thermosetting binder preferably has an exothermic peak temperature higher than the melting point of the solder particles and preferably has a minimum melt viscosity temperature lower than the melting point of the solder particles. This allows the thermosetting binder to be melted by heating, the solder particles to be aggregated on the terminals, and then the thermosetting binder to be hardened. Here, the exothermic peak temperature and the minimum melt viscosity temperature can be measured using, for example, a rotational rheometer (manufactured by Thermo Fisher Scientific) under the following conditions: measurement pressure 1 N, temperature range 30 to 200° C., heating rate 10° C./min, measurement frequency 1 Hz, and measurement plate diameter 8 mm.

Examples of the thermosetting binder include a thermal radical polymerization type resin composition containing a (meth)acrylate compound and a thermal radical polymerization initiator, a thermal cationic polymerization type resin composition containing an epoxy compound and a thermal cationic polymerization initiator, a thermal anionic polymerization type resin composition containing an epoxy compound and a thermal anionic polymerization initiator, and the like. Also, known pressure-sensitive adhesive compositions may be used. Note that (meth)acrylic monomers include both acrylic monomers and methacrylic monomers.

Specific example will be described below, using thermally polymerizable resin composition containing a solid epoxy resin, a liquid epoxy resin, and an epoxy resin curing agent as examples.

The solid epoxy resin is not particularly limited as long as it is solid at room temperature and has one or more epoxy groups in the molecule and may be, for example, a bisphenol A type epoxy resin, a biphenyl type epoxy resin, and the like. Among these, it is preferable to use a crystalline bisphenol A type epoxy resin having a low melt viscosity. A specific example of a commercially available crystalline bisphenol A epoxy resin is Mitsubishi Chemical Corporation's product “YL6810” (crystalline BPA epoxy resin), which has a viscosity of 40 to 55 P as measured by the Gardner-Holdt method, or the like. The solid epoxy resin may also be a phenoxy resin synthesized from bisphenols and epichlorohydrin. Examples of the phenoxy resin include “YP-50” made by Nippon Steel Chemical & Material Co., Ltd, and the like. This allows the film shape to be maintained. Note that normal temperature is the range of 20° C.±15° C. (5° C. to 35° C.) as specified in JIS Z8703.

The liquid epoxy resin is not particularly limited as long as it is liquid at room temperature, and may be, for example, a bisphenol A type epoxy resin, a bisphenol F type epoxy resin, a hydrogenated bisphenol A glycidyl ether, a urethane-modified epoxy resin, or the like. An example of the bisphenol F type epoxy resin is “YL 983 U” manufactured by Mitsubishi Chemical Corporation, and an example of the hydrogenated bisphenol A glycidyl ether is “YX8000” manufactured by Mitsubishi Chemical Corporation, or the like.

The amount of the liquid epoxy resin to be blended is preferably 160 parts by mass or less, more preferably 140 parts by mass or less, and even more preferably 120 parts by mass or less, per 100 parts by mass of the solid epoxy resin. When the amount of liquid epoxy resin added is too large, it becomes difficult to maintain the film shape. Furthermore, when the blending amount of the liquid epoxy resin is large, the cured physical properties after heat curing generally become high elasticity due to high crosslink density, and therefore the stress relaxation capability decreases.

The epoxy resin curing agent is not particularly limited as long as it is a heat curing agent that initiates curing by heat, and examples thereof include anionic curing agents such as amines and imidazoles, and cationic curing agents such as sulfonium salts. The curing agent may also be microencapsulated to provide resistance to the solvent used in forming the film. Examples of anionic curing agents include imidazole epoxy resin curing agents such as “2P4MHZ-PW” manufactured by Shikoku Kasei.

### [Solder Particles]

The solder particles can be appropriately selected from, for example, Sn—Pb, Pb—Sn—Sb, Sn—Sb, Sn—Pb—Bi, Bi—Sn, Sn—Cu, Sn—Pb—Cu, Sn—In, Sn—Ag, Sn—Pb—Ag, Pb—Ag, and the like, as specified in JIS Z3282-1999, depending on the electrode material, connection conditions, and the like. Among these, the solder particles are preferably one or more selected from the group consisting of an Sn—Bi—Cu alloy, an Sn—Bi—Ag alloy, an Sn—Bi alloy, an Sn—Pb—Bi alloy, and an Sn—In alloy. Specific examples of solder particles include Sn59.9Bi40Cu0.1, Sn30Bi0.5Cu, Sn30Bi, Sn40Bi, Sn50Bi, Sn58Bi, Sn40Bi0.1Cu, Sn43Pb14Bi, Sn20In, and the like. This makes it possible to obtain excellent connection reliability.

A lower limit of the melting point of the solder particles is preferably 110° C. or more, more preferably 120° C. or more, and even more preferably 130° C. or more. An upper limit of the melting point of the solder particles is 250° C. or less, preferably 200° C. or less, more preferably 180° C. or less, and even more preferably 160° C. or less. Furthermore, the solder particles may have a flux compound directly bonded to the surface for the purpose of activating the surface. Activating the surface can promote metallic bonding with the electrode portion.

The average particle size of the solder particles is preferably 0.5 times or less, more preferably 0.3 times or less, and even more preferably 0.2 times or less, of the minimum inter-terminal distance (inter-space distance) in the terminal row of the surface mount device and the terminal row of the wiring board. Due to the relationship between the spacing distance and the average particle size of the solder particles, the terminal rows of the surface mount devices and the terminal rows of the wiring board may be joined using a reflow furnace. When the average particle size of the solder particles is larger than 0.5 times the minimum distance between the terminals in the terminal rows of the surface mount device and the wiring board, the possibility of a short circuit occurring increases.

A lower limit of the average particle size of the solder particles is preferably 0.5 μm or more, more preferably 3 μm or more, and more preferably 5 μm or more, and an upper limit of the average particle size of the solder particles may be 50 μm or less, and is 30 μm or less, preferably 25 μm or less, and more preferably 20 μm or less. This makes it possible to obtain a favorable solder joint state and high reliability.

The average particle size is the average value of a major axis diameter of particles measured, for example, at N=20 or more, preferably N=50 or more, and more preferably N=200 or more in an observation image using a metallurgical microscope, an optical microscope, or an electron microscope such as an SEM (Scanning Electron Microscope), and when the particles are spherical, it is the average value of the diameter of the particles. Alternatively, the observed image may be a measurement value obtained by using known image analysis software (such as “WinROOF”: Mitani Corporation; “Azo-kun (registered trademark)”: Asahi Kasei Engineering Corporation) or a measurement value (N=1000 or more) obtained by using an image-based particle size distribution analyzer (for example, FPIA-3000 (Malvern)). The average particle size determined from an observed image or an image-type particle size distribution analyzer may be used as the average value of the highest length particles. When producing a solder connection film, it is also possible to use manufacturer values such as the particle size (D50) at which the cumulative frequency in the particle size distribution simply determined by a laser diffraction/scattering method is 50%, or the arithmetic mean diameter (preferably on a volume basis).

The solder particles are preferably dispersed in a binder, and the solder particles may be disposed randomly or according to a certain rule. The solder particles may also be in the form of an aggregate of a plurality of particles.

The content of solder particles in the solder connection film can be determined appropriately based on the pitch of the terminal rows of the surface mount devices and the wiring board, and for example, it is preferably 10% to 60% by volume for a terminal row pitch of 0.1 mm to 0.4 mm of the surface mount devices and the wiring board. For example, it is preferably 20% to 58% by volume when the pitch is 0.4 mm, 20% to 58% by volume when the pitch is 0.35 mm, 20% to 48% by volume when the pitch is 0.2 mm, 15% to 48% by volume when the pitch is 0.15 mm, and 10% to 38% by volume when the pitch is 0.1 mm. When the content of solder particles is too low, excellent conductivity, heat dissipation, and adhesiveness cannot be obtained, whereas when the content is too high, the anisotropy is easily impaired, making it difficult to obtain excellent reliability of conduction.

### [Flux Compound]

A flux compound removes foreign matter and oxide films from an electrode surface, prevents oxidation of the electrode surface, and reduces the surface tension of molten solder. Examples of flux compounds include carboxylic acids such as levulinic acid, maleic acid, oxalic acid, malonic acid, succinic acid, glutaric acid, adipic acid, and sebacic acid. Among these, it is preferable to use glutaric acid, which is excellent at removing oxide films.

### [Other Additives]

In addition to the binder, solder particles, and flux compound described above, the solder connection film may contain various additives that have traditionally been used as adhesives, as long as they do not impair the effects of the present art. The particle size of additives is preferably smaller than the average particle size of the solder particles but is not particularly limited as long as it does not impede the bonding between the electrodes.

The foregoing solder connection film may be obtained, for example, by mixing an insulating binder, solder particles, and a flux compound in a solvent, applying this mixture to a release-treated film to a predetermined thickness using a bar coater, and then drying it to volatilize the solvent. Alternatively, the mixture may be applied to a release-treated film using a bar coater, and then pressed to a predetermined thickness. In order to improve dispersibility of the solder particles, it is preferable to apply a high shear force while the solder contains a solvent. For example, a known batch type planetary mixing device may be used. The amount of residual solvent in the solder connection film is preferably 2% or less, and more preferably 1% or less.

According to the solder connection film of the present embodiment, removal of the oxide film by the flux compound is moderately suppressed, making it easier for the solder to remain at a moderate level, and thus the remaining solder area can be kept within a moderate range. Furthermore, by keeping the remaining solder area within an appropriate range, moisture permeation resistance and mechanical strength are improved, and a decrease in bonding strength and an increase in resistance value can be suppressed.

### EXAMPLES

### 3. First Example

In a first example, an anisotropic conductive film containing solder particles was produced as an embodiment of a solder connection film. Then, a connector was mounted on a substrate having a first terminal row and a second terminal row using the anisotropic conductive film, and the connection structure after reflow was evaluated for bridge formation, conduction resistance, solder residue, and solder height.

### [Preparation of Anisotropic Conductive Film]

A binder was prepared by blending 45 parts by mass of phenoxy resin (YP-50, Nippon Steel Chemical & Material Co., Ltd.), 10 parts by mass of hydrogenated bisphenol A glycidyl ether (YX8000, Mitsubishi Chemical Corporation), 45 parts by mass of crystalline bisphenol A epoxy resin (YL6810, Mitsubishi Chemical Corporation), 10 parts by mass of an imidazole-based epoxy resin curing agent (2P4MHZ-PW (2-phenyl-4-methyl-5-hydroxymethylimidazole), Shikoku Chemical Industry Co., Ltd.), and 8 parts by mass of glutaric acid (1,3-propanedicarboxylic acid, Tokyo Chemical Industry Co., Ltd.). A predetermined amount of solder particles (Sn59.9Bi40Cu0.1) having an average particle size of 20 μm was mixed with 118 parts by mass of binder to prepare an anisotropic conductive film of a predetermined thickness.

### [Preparation of Connection Structure]

A printed wiring board (having a first terminal row and a second terminal row, with the distance between the first terminal row and the second terminal row being 0.8 mm; the first terminal row and second terminal row had a 0.35 mm pitch (line/space=0.18/0.17 mm, terminal length 0.8 mm), a glass epoxy substrate thickness of 1.5 mm, a copper pattern thickness of 18 μm, and an OSP surface treatment) was prepared as the substrate.

As connectors, a plug connector (BM23FR0.6-20DP made by Hirose, 10 pins on one side (20 pins on both sides), 0.35 mmP, line/space=0.12/0.23 mm, terminal surface Au plated) and a receptacle connector (BM23FR0.6-20DS made by Hirose, 10 pins on one side (20 pins on both sides), 0.35 mm P, line/space=0.12/0.23 mm, terminal surface Au plated) were prepared.

The anisotropic conductive film was cut to a predetermined size and temporarily pressed onto the terminals of the substrate under conditions of 45° C., 1 MPa, and 1 second to temporarily attach the anisotropic conductive film onto the terminals of the substrate. Next, connectors (plug connector and receptacle connector) were placed on the anisotropic conductive film, and reflow was carried out under the following reflow conditions to prepare a connection structure.

Reflow conditions: 150° C. to 260° C. for 100 seconds, peak temperature set at 260° C.

### [Evaluation of Bridging Occurrence]

For the connection structure after reflow, an insulation resistance value when a voltage of 20 V was applied between adjacent terminals was measured using a digital multimeter. A resistance of 10⁶Ω or less was counted as occurrence of a solder bridge.

### [Evaluation of Conduction Resistance]

The connection structure after reflow was measured for conduction resistance when DC 10 mA was applied using a four-terminal method with a digital multimeter, and evaluation was based on the maximum resistance value. The evaluation criteria for A to C were as follows:
A: Maximum resistance value is 50 mΩ or less
B: Maximum resistance value exceeds 50 mΩ and is 90 mΩ or less
C: Maximum resistance value exceeds 90 mΩ

### [Evaluation of Solder Residue]

After reflow, the connection structure was subjected to an X-ray photograph using an X-ray photography device to determine whether or not there was any solder remaining outside the terminals.

### [Evaluation of Solder Height]

For the connection structure after reflow, a cross-section between the terminal of the first electronic component and the pin of the second component was observed using an electron microscope, the height (thickness) of the solder was measured, and the average value, standard deviation σ, and relative standard deviation (RSD, Relative Standard Deviation) were calculated.

### Example 1

460 parts by mass of solder particles was mixed into 118 parts by mass of binder to prepare an anisotropic conductive film having a thickness of 40 μm, which was then cut to a width of 0.8 mm.

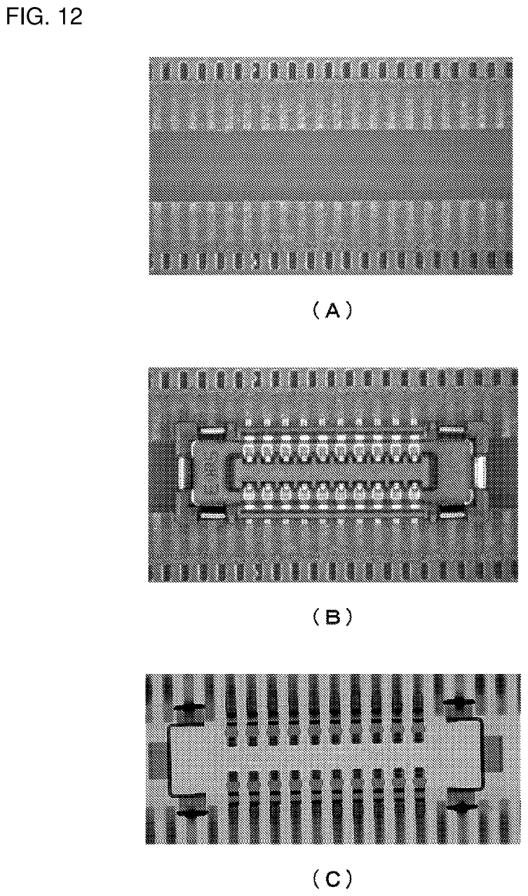

FIG. 12(A) is a photograph showing a state in which a anisotropic conductive film is temporarily bonded on a printed wiring board for Example 1, FIG. 12(B) is a photograph showing a state in which a connector is mounted on a printed circuit board for Example 1, and FIG. 12(C) is an X-ray photograph showing the connection structure after reflow for Example 1. The anisotropic conductive film having a width of 0.8 mm were temporarily attached on the first terminal row and the second terminal row, respectively, a gap having a width of 0.8 mm was provided between the first terminal row and the second terminal row, and the connector was mounted.

As shown in Table 1, the connection structure of Example 1 did not any bridges occur, the evaluation of the electrical resistance was A, and there was no solder residue as shown in the X-ray photograph in FIG. 12(C). Furthermore, the average solder height was 51 μm, the standard deviation was 6 μm, and the relative standard deviation was 12%.

### Example 2

A connection structure was produced in the same manner as in Example 1, except that 690 parts by mass of solder particles were mixed into 118 parts by mass of binder to produce an anisotropic conductive film having a thickness of 40 μm. As illustrated in Table 1, the connection structure of Example 2 did not have a bridge occurred, the evaluation of the conduction resistance was A, and there was no solder residue. Furthermore, the average solder height was 60 μm, the standard deviation was 7 μm, and the relative standard deviation was 12%.

### Example 3

A connection structure was produced in the same manner as in Example 1, except that 1040 parts by mass of solder particles were mixed into 118 parts by mass of binder to produce an anisotropic conductive film having a thickness of 40 μm. As illustrated in Table 1, the connection structure of Example 3 did not have a bridge occur, the evaluation of the conduction resistance was A, and there was no solder residue. Furthermore, the average solder height was 71 μm, the standard deviation was 8 μm, and the relative standard deviation was 11%.

### Comparative Example 1

300 parts by mass of solder particles was mixed into 118 parts by mass of binder to prepare an anisotropic conductive film having a thickness of 40 μm, which was then cut to a width of 2.4 mm.

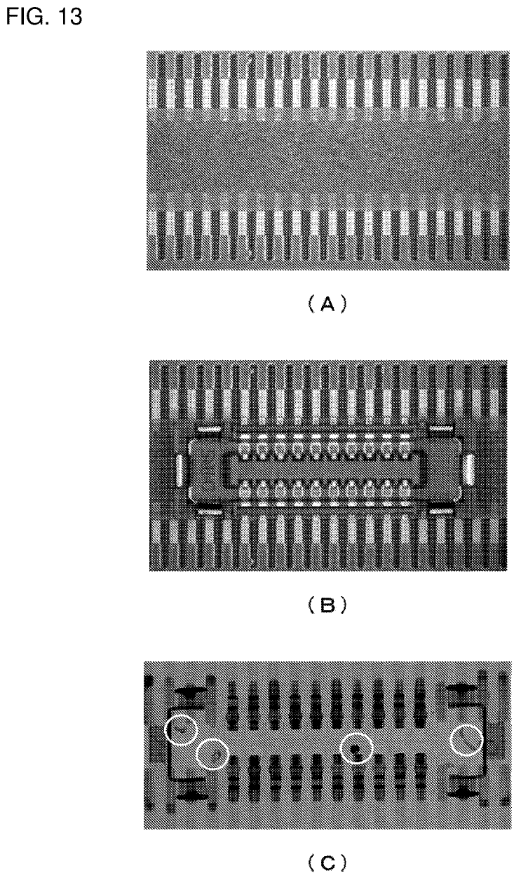

FIG. 13(A) is a photograph showing a state in which an anisotropic conductive film is temporarily bonded on a printed wiring board for Comparative Example 1, FIG. 13(B) is a photograph showing a state in which a connector is mounted on a printed circuit board for Comparative Example 1, and FIG. 13(C) is an X-ray photograph showing a connection structure after reflow for Comparative Example 1. The anisotropic conductive film having a width of 2.4 mm was temporarily bonded on the entire surface including the first terminal row and the second terminal row, and the connector was mounted.

As shown in Table 1, the connection structure of Comparative Example 1 did not have any bridges occur, the evaluation of the electrical resistance was B, and there was solder residue as shown in the X-ray photograph in FIG. 13(C). Furthermore, the average solder height was 48 μm, the standard deviation was 17 μm, and the relative standard deviation was 35%.

### Comparative Example 2

A connection structure was produced in the same manner as in Comparative Example 1, except that 460 parts by mass of solder particles were mixed into 118 parts by mass of binder to produce an anisotropic conductive film having a thickness of 40 μm. As illustrated in Table 1, the connection structure of Comparative Example 2 had a bridge occurrence (3ch), the evaluation of the conduction resistance was C, and there was solder residue. Furthermore, the average value of the solder height was 74 μm, the standard deviation was 21 μm, and the relative standard deviation was 28%.

### Comparative Example 3

A connection structure was produced in the same manner as in Comparative Example 1, except that 460 parts by mass of solder particles were mixed into 118 parts by mass of binder to produce an anisotropic conductive film having a thickness of 30 μm. As shown in Table 1, the connection structure of Comparative Example 3 did not have a bridge occur, the evaluation of the conduction resistance was B, and there was solder residue. Furthermore, the average value of the solder height was 59 μm, the standard deviation was 23 μm, and the relative standard deviation was 39%.

### Comparative Example 4

A connection structure was produced in the same manner as in Comparative Example 1, except that 690 parts by mass of solder particles were mixed into 118 parts by mass of binder to produce an anisotropic conductive film having a thickness of 40 μm. As illustrated in Table 1, the connection structure of Comparative Example 4 had a bridge occurrence (2ch), the evaluation of the conduction resistance was C, and there was solder residue. Furthermore, the average value of the solder height was 87 μm, the standard deviation was 25 μm, and the relative standard deviation was 29%.

TABLE 1

| | | Example | Example | Example | Comparative | Comparative | Comparative | Comparative |
|---|---|---|---|---|---|---|---|---|
| | | 1 | 2 | 3 | Example 1 | Example 2 | Example 3 | Example 4 |
| Binder [parts by | | 118 | 118 | 118 | 118 | 118 | 118 | 118 |
| weight] | | | | | | | | |
| Solder particles | | 460 | 690 | 1040 | 300 | 460 | 460 | 690 |
| [parts by mass] | | | | | | | | |
| Total [parts by | | 578 | 808 | 1158 | 418 | 578 | 578 | 808 |
| mass] | | | | | | | | |
| Particle amount | | 38 | 48 | 58 | 28 | 38 | 38 | 48 |
| [vol %] | | | | | | | | |
| Film thickness | | 40 | 40 | 40 | 40 | 40 | 30 | 40 |
| [μm] | | | | | | | | |
| How to apply | | 2-row pasting | | | Full surface pasting | | | |
| Film width [mm] | | 0.8 | | | 2.4 | | | |
| Gap [mm] | | 0.8 | | | — | | | |
| Bridge occurrence | | 0/40 | 0/40 | 0/40 | 0/40 | 3/40 | 0/40 | 2/40 |
| location [ch] | | | | | | | | |
| Conduction | | A | A | A | B | C | B | C |
| resistance | | | | | | | | |
| evaluation | | | | | | | | |
| Solder residue | | No | No | No | Yes | Yes | Yes | Yes |
| evaluation | | | | | | | | |
| Solder | Ave [μm] | 51 | 60 | 71 | 48 | 74 | 59 | 87 |
| height | σ [μm] | 6 | 7 | 8 | 17 | 21 | 23 | 25 |
| | RSD [%] | 12 | 12 | 11 | 35 | 28 | 39 | 29 |

In Comparative Examples 1 to 4, the anisotropic conductive film was temporarily bonded on the entire surface including the first terminal row and the second terminal row, and thus solder remained between the first terminal row and the second terminal row, and the standard deviation and relative standard deviation of the solder height were high. This is thought to be because the solder particles move between the first terminal row and second terminal row, making it inefficient for the solder particles to aggregate on the terminals.

Conversely, in Examples 1 to 3, the anisotropic conductive film was temporarily bonded on the first terminal row and the second terminal row, respectively, and thus there was no solder residue between the first terminal row and the second terminal row, and the standard deviation and the relative standard deviation of the solder height were low. This is thought to be because the solder particles do not move between the first terminal row and second terminal row, making it efficient for the solder particles to aggregate on the terminals.

### 4. Second Example

In a second example, an anisotropic conductive film was temporarily bonded on a substrate having a first terminal row and a second terminal row, reflow was performed, and the occurrence of bridging and solder height were evaluated.

A printed wiring board (having a first terminal row and a second terminal row, with the distance between the first terminal row and the second terminal row being 0.8 mm; the first terminal row and second terminal row had a 0.35 mm pitch (line/space=0.18/0.17 mm, terminal length 0.8 mm), a glass epoxy substrate thickness of 1.5 mm, a copper pattern thickness of 18 μm, and an OSP surface treatment) was prepared as the substrate.

The anisotropic conductive film was cut to a predetermined size on a terminal of the substrate, temporary crimping was performed under conditions of 45° C., 1 MPa, and 1 second, the anisotropic conductive film was temporarily bonded on the terminal of the substrate, and reflow was performed under the following reflow conditions to manufacture the sample.

Reflow conditions: 150° C. to 260° C. for 100 seconds, peak temperature set at 260° C.

### [Evaluation of Bridging Occurrence]

For the sample after reflow, an insulation resistance value when a voltage of 20 V was applied between adjacent terminals was measured using a digital multimeter. A resistance of 10⁶Ω or less was counted as the occurrence of a solder bridge, and a test piece in which no bridge occurred was evaluated as “OK”, while a test piece in which a bridge occurred was evaluated as “NG”.

### [Evaluation of Solder Height]

The solder height (thickness) on the wiring of the sample after reflow was measured using a 3D measuring laser microscope (LEXT OLS5000, made by Olympus Corporation), and the average value, standard deviation σ, and relative standard deviation (RSD, Relative Standard Deviation) were calculated.

### [Preparation of Anisotropic Conductive Film]

A binder was prepared by blending 45 parts by mass of phenoxy resin (YP-50, Nippon Steel Chemical & Material Co., Ltd.), 10 parts by mass of hydrogenated bisphenol A glycidyl ether (YX8000, Mitsubishi Chemical Corporation), 45 parts by mass of crystalline bisphenol A epoxy resin (YL6810, Mitsubishi Chemical Corporation), 10 parts by mass of an imidazole-based epoxy resin curing agent (2P4MHZ-PW (2-phenyl-4-methyl-5-hydroxymethylimidazole), Shikoku Chemical Industry Co., Ltd.), and 8 parts by mass of glutaric acid (1,3-propanedicarboxylic acid, Tokyo Chemical Industry Co., Ltd.). A predetermined amount of solder particles (Sn59.9Bi40Cu0.1) having an average particle size of 20 μm was mixed with 118 parts by mass of binder to prepare an anisotropic conductive film of a predetermined thickness.

### Example 4

460 parts by mass of solder particles was mixed into 118 parts by mass of binder to prepare an anisotropic conductive film having a thickness of 40 μm, which was then cut to a width of 1.2 mm. An anisotropic conductive film having a width of 1.2 mm was temporarily bonded on each of the first terminal row and second terminal row, and a gap having a width of 0 mm was provided between the first terminal row and second terminal row. As illustrated in Table 2, the sample of Example 4 was evaluated as OK for bridge occurrence, the average solder height was 58.8 μm, the standard deviation was 8.4 μm, and the relative standard deviation was 14%.

### Example 5

460 parts by mass of solder particles was mixed into 118 parts by mass of binder to prepare an anisotropic conductive film having a thickness of 40 μm, which was then cut to a width of 1.0 mm. An anisotropic conductive film having a width of 1.0 mm was temporarily bonded on each of the first terminal row and second terminal row, and a gap having a width of 0.4 mm was provided between the first terminal row and second terminal row. As illustrated in Table 2, the sample of Example 5 had an evaluation of bridge occurrence of OK, the average value of solder height was 56.8 μm, the standard deviation was 5.8 μm, and the relative standard deviation was 10%.

### Example 6

460 parts by mass of solder particles was mixed into 118 parts by mass of binder to prepare an anisotropic conductive film having a thickness of 40 μm, which was then cut to a width of 0.8 mm. An anisotropic conductive film having a width of 0.8 mm was temporarily bonded on each of the first terminal row and second terminal row, and a gap having a width of 0.8 mm was provided between the first terminal row and second terminal row. As illustrated in Table 2, the sample of Embodiment 6 had an evaluation of bridge occurrence of OK, the average value of solder height was 44.3 μm, the standard deviation was 5.3 μm, and the relative standard deviation was 14%.

### Example 7

460 parts by mass of solder particles was mixed into 118 parts by mass of binder to prepare an anisotropic conductive film having a thickness of 40 μm, which was then cut to a width of 0.6 mm. An anisotropic conductive film having a width of 0.6 mm was temporarily bonded on each of the first terminal row and second terminal row, and a gap having a width of 1.2 mm was provided between the first terminal row and second terminal row. As illustrated in Table 2, the sample of Example 7 had an evaluation of bridge occurrence of OK, the average solder height was 42.8 μm, the standard deviation was 3.8 μm, and the relative standard deviation was 9%.

### Example 8

460 parts by mass of solder particles was mixed into 118 parts by mass of binder to prepare an anisotropic conductive film having a thickness of 40 μm, which was then cut to a width of 0.4 mm. An anisotropic conductive film having a width of 0.4 mm was temporarily bonded on each of the first terminal row and second terminal row, and a gap having a width of 1.6 mm was provided between the first terminal row and second terminal row. As illustrated in Table 2, the sample of Example 8 had an evaluation of bridge occurrence of OK, the average value of solder height was 42.2 μm, the standard deviation was 8.5 μm, and the relative standard deviation was 20%.

### Comparative Example 5

460 parts by mass of solder particles was mixed into 118 parts by mass of binder to prepare an anisotropic conductive film having a thickness of 40 μm, which was then cut to a width of 2.4 mm. The anisotropic conductive film having a width of 2.4 mm was temporarily bonded on the entire surface including the first terminal row and the second terminal row. As illustrated in Table 2, the sample of Comparative Example 5 had an evaluation of bridge occurrence of NG, the average value of solder height was 57.0 μm, the standard deviation was 14.0 μm, and the relative standard deviation was 25%.

TABLE 2

| | | Example | Example | Example | Example | Example | Comparative |
|---|---|---|---|---|---|---|---|
| | | 4 | 5 | 6 | 7 | 8 | Example 5 |
| Binder [parts by weight] | | 118 | | | | | |
| Solder particles [parts by mass] | | 460 | | | | | |
| Total [parts by mass] | | 578 | | | | | |
| Particle amount [vol %] | | 38 | | | | | |
| Film thickness [μm] | | 40 | | | | | |
| How to apply | | 2-row | 2-row | 2-row | 2-row | 2-row | Full surface |
| | | pasting | pasting | pasting | pasting | pasting | pasting |
| Film width [mm] | | 1.2 | 1.0 | 0.8 | 0.6 | 0.4 | 2.4 |
| Gap [mm] | | 0 | 0.4 | 0.8 | 1.2 | 1.6 | — |
| Evaluation of bridging occurrence | | OK | OK | OK | OK | OK | NG |
| Solder height | Ave [μm] | 58.8 | 56.8 | 44.3 | 42.8 | 42.2 | 57.0 |
| | σ [μm] | 8.4 | 5.8 | 6.3 | 3.8 | 8.5 | 14.0 |
| | RSD [%] | 14 | 10 | 14 | 9 | 20 | 25 |

In Comparative Example 5, an anisotropic conductive film was temporarily bonded on the entire surface including the first terminal row and the second terminal row, and thus bridging occurred, and the standard deviation and relative standard deviation of the solder height were high. This is thought to be because the solder particles move between the first terminal row and second terminal row, making it inefficient for the solder particles to aggregate on the terminals.

Conversely, in Examples 4 to 8, the anisotropic conductive films are temporarily bonded to the first terminal row and the second terminal row, respectively, and thus no bridge occurs, and the standard deviation and relative standard deviation of the solder height are low. In addition, in Examples 5 to 7, the protrusion amount of the rectangular portions in the width direction of the first and second anisotropic conductive films disposed between the first terminal row and second terminal row, respectively, was 25% or less, thereby further reducing the standard deviation and relative standard deviation of the solder height. This is thought to be due to the efficient aggregation of solder particles onto the terminals.

### Example 9

690 parts by mass of solder particles was mixed into 118 parts by mass of binder to prepare an anisotropic conductive film having a thickness of 40 μm, which was then cut to a width of 1.2 mm. An anisotropic conductive film having a width of 1.2 mm was temporarily bonded on each of the first terminal row and second terminal row, and a gap having a width of 0 mm was provided between the first terminal row and second terminal row. As illustrated in Table 3, the sample of Example 9 had an evaluation of bridge occurrence of OK, the average value of solder height was 67.5 μm, the standard deviation was 9.7 μm, and the relative standard deviation was 14%.

### Example 10

690 parts by mass of solder particles was mixed into 118 parts by mass of binder to prepare an anisotropic conductive film having a thickness of 40 μm, which was then cut to a width of 1.0 mm. An anisotropic conductive film having a width of 1.0 mm was temporarily bonded on each of the first terminal row and second terminal row, and a gap having a width of 0.4 mm was provided between the first terminal row and second terminal row. As illustrated in Table 3, the sample of Example 10 had an evaluation of bridge occurrence of OK, the average solder height was 66.0 μm, the standard deviation was 7.9 μm, and the relative standard deviation was 12%.

### Example 11

690 parts by mass of solder particles was mixed into 118 parts by mass of binder to prepare an anisotropic conductive film having a thickness of 40 μm, which was then cut to a width of 0.8 mm. An anisotropic conductive film having a width of 0.8 mm was temporarily bonded on each of the first terminal row and second terminal row, and a gap having a width of 0.8 mm was provided between the first terminal row and second terminal row. As illustrated in Table 3, the sample of Example 11 had an evaluation of bridge occurrence of OK, the average value of solder height was 50.5 μm, the standard deviation was 6.4 μm, and the relative standard deviation was 13%.

### Example 12

690 parts by mass of solder particles was mixed into 118 parts by mass of binder to prepare an anisotropic conductive film having a thickness of 40 μm, which was then cut to a width of 0.6 mm. An anisotropic conductive film having a width of 0.6 mm was temporarily bonded on each of the first terminal row and second terminal row, and a gap having a width of 1.2 mm was provided between the first terminal row and second terminal row. As illustrated in Table 3, the sample of Example 12 had an evaluation of bridge occurrence of OK, the average solder height was 48.4 μm, the standard deviation was 4.7 μm, and the relative standard deviation was 10%.

### Example 13

690 parts by mass of solder particles was mixed into 118 parts by mass of binder to prepare an anisotropic conductive film having a thickness of 40 μm, which was then cut to a width of 0.4 mm. An anisotropic conductive film having a width of 0.4 mm was temporarily bonded on each of the first terminal row and second terminal row, and a gap having a width of 1.6 mm was provided between the first terminal row and second terminal row. As illustrated in Table 3, the sample of Example 13 had an evaluation of bridge occurrence of OK, the average solder height was 49.0 μm, the standard deviation was 8.1 μm, and the relative standard deviation was 17%.

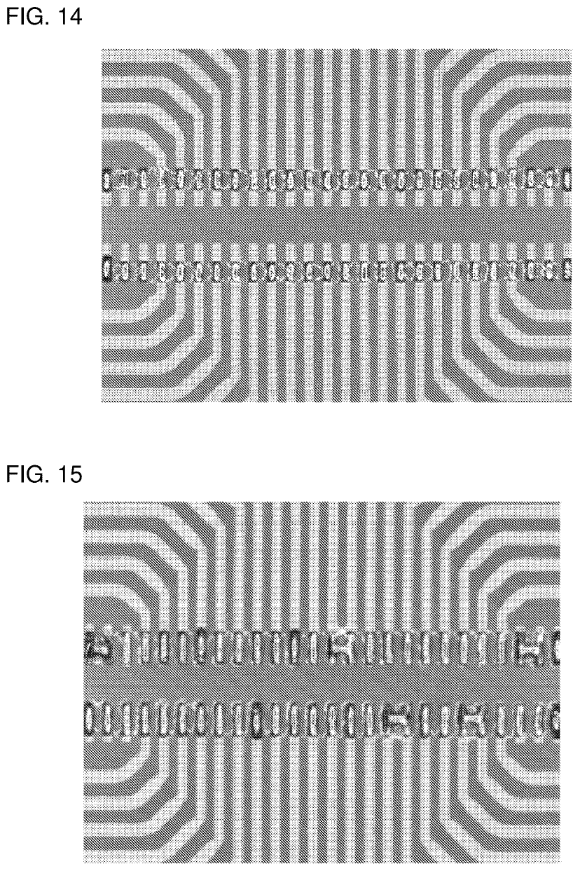

FIG. 14 is a photograph showing a sample after reflow for Example 13. The photograph in FIG. 14 shows that there is no residual solder in the gap and that a solder joint without bridging has been formed. It can also be seen that solder joints are formed in parts of the terminals to which the anisotropic conductive film is attached.

### Comparative Example 6

690 parts by mass of solder particles was mixed into 118 parts by mass of binder to prepare an anisotropic conductive film having a thickness of 40 μm, which was then cut to a width of 2.4 mm. The anisotropic conductive film having a width of 2.4 mm was temporarily pasted on the entire surface including the first terminal row and the second terminal row. As illustrated in Table 3, the samples of Comparative Example 6 had an evaluation of bridge occurrence of NG, the average value of solder height was 88.2 μm, the standard deviation was 28.5 μm, and the relative standard deviation was 32%.

FIG. 15 is a photograph showing a sample after reflow for Comparative Example 6. The photograph illustrated in FIG. 15 reveals that a solder joint with bridging has been formed. It can also be seen that solder joints are formed in all of the terminals to which the anisotropic conductive film is attached.

TABLE 3

| | | Example | Example | Example | Example | Example | Comparative |
|---|---|---|---|---|---|---|---|
| | | 9 | 10 | 11 | 12 | 13 | Example 6 |
| Binder [parts by weight] | | 118 | | | | | |
| Solder particles [parts by mass] | | 690 | | | | | |
| Total [parts by mass] | | 808 | | | | | |
| Particle amount [vol %] | | 48 | | | | | |
| Film thickness [μm] | | 40 | | | | | |
| How to apply | | 2-row | 2-row | 2-row | 2-row | 2-row | Full surface |
| | | pasting | pasting | pasting | pasting | pasting | pasting |
| Film width [mm] | | 1.2 | 1.0 | 0.8 | 0.6 | 0.4 | 2.4 |
| Gap [mm] | | 0 | 0.4 | 0.8 | 1.2 | 1.6 | — |
| Evaluation of bridging occurrence | | OK | OK | OK | OK | OK | NG |
| Solder height | Ave [μm] | 67.5 | 66.0 | 50.5 | 48.4 | 49.0 | 88.2 |
| | σ [μm] | 9.7 | 7.9 | 6.4 | 4.7 | 8.1 | 28.5 |
| | RSD [%] | 14 | 12 | 13 | 10 | 17 | 32 |

In Comparative Example 6, an anisotropic conductive film was temporarily bonded on the entire surface including the first terminal row and the second terminal row, and thus bridging occurred, and the standard deviation and relative standard deviation of the solder height were high. This is thought to be because the solder particles move between the first terminal row and second terminal row, making it inefficient for the solder particles to aggregate on the terminals.

Conversely, in Examples 9 to 13, the anisotropic conductive films are temporarily bonded to the first terminal row and the second terminal row, respectively, and thus no bridge occurs, and the standard deviation and relative standard deviation of the solder height are low. In addition, in Examples 10 to 21, the protrusion amount of the rectangular portions in the width direction of the first and second anisotropic conductive films disposed between the first terminal row and second terminal row, respectively, was 25% or less, thereby further reducing the standard deviation and relative standard deviation of the solder height. This is thought to be due to the efficient aggregation of solder particles onto the terminals.

### 5. Third Example

In a third example, an anisotropic conductive film was temporarily bonded on a substrate having a first terminal row to a fourth terminal row, reflow was performed, and the occurrence of bridging and solder height were evaluated.

A printed wiring board (a first terminal row to a fourth terminal row are disposed in a rectangular shape and wired on the outside, with no terminals inside the rectangle; the first terminal row to fourth terminal row each having a 0.2 mm pitch (line/space=0.1/0.1 mm, terminal length 0.6 mm), 40 pins (8 mm), glass epoxy substrate thickness 1.5 mm, copper pattern thickness 18 μm, surface OSP treatment) was prepared as the substrate.

The anisotropic conductive film was cut to a predetermined size on a terminal of the substrate, temporary crimping was performed under conditions of 45° C., 1 MPa, and 1 second, the anisotropic conductive film was temporarily bonded on the terminal of the substrate, and reflow was performed under the following reflow conditions to manufacture the sample.

Reflow conditions: 150° C. to 260° C. for 100 seconds, peak temperature set at 260° C.

### [Evaluation of Bridging Occurrence]

For the sample after reflow, an insulation resistance value when a voltage of 20 V was applied between adjacent terminals was measured using a digital multimeter. A resistance of 10⁶Ω or less was counted as the occurrence of a solder bridge, and a test piece in which no bridge occurred was evaluated as “OK”, while a test piece in which a bridge occurred was evaluated as “NG”.

### [Evaluation of Solder Height]

The solder height (thickness) on the wiring of the sample after reflow was measured using a 3D measuring laser microscope (LEXT OLS5000, made by Olympus Corporation), and the average value, standard deviation σ, and relative standard deviation (RSD, Relative Standard Deviation) were calculated.

### [Preparation of Anisotropic Conductive Film]

A binder was prepared by blending 45 parts by mass of phenoxy resin (YP-50, Nippon Steel Chemical & Material Co., Ltd.), 10 parts by mass of hydrogenated bisphenol A glycidyl ether (YX8000, Mitsubishi Chemical Corporation), 45 parts by mass of crystalline bisphenol A epoxy resin (YL6810, Mitsubishi Chemical Corporation), 10 parts by mass of an imidazole-based epoxy resin curing agent (2P4MHZ-PW (2-phenyl-4-methyl-5-hydroxymethylimidazole), Shikoku Chemical Industry Co., Ltd.), and 8 parts by mass of glutaric acid (1,3-propanedicarboxylic acid, Tokyo Chemical Industry Co., Ltd.). A predetermined amount of solder particles (Sn59.9Bi40Cu0.1) having an average particle size of 20 μm was mixed with 118 parts by mass of binder to prepare an anisotropic conductive film of a predetermined thickness.

### Example 14

204 parts by mass of solder particles were mixed into 118 parts by mass of binder to prepare an anisotropic conductive film having a thickness of 40 μm, which was then cut to a width of 0.6 mm and a length of 8 mm. Anisotropic conductive films having a width of 0.6 mm were temporarily bonded on the first terminal row to fourth terminal row. As illustrated in Table 4, the sample of Example 14 had an evaluation of bridge occurrence of OK, the average solder height was 24.5 μm, the standard deviation was 4.0 μm, and the relative standard deviation was 17%.

### Comparative Example 7

204 parts by mass of solder particles were mixed into 118 parts by mass of binder to prepare an anisotropic conductive film having a thickness of 40 μm, which was then cut to a width of 9.2 mm and a length of 9.2 mm. The anisotropic conductive film of 9.2 mm×9.2 mm was temporarily bonded on the entire surface, including the first terminal row to the fourth terminal row. As illustrated in Table 4, the sample of Comparative Example 7 had an evaluation of bridge occurrence of NG, the average value of solder height was 17.7 μm, the standard deviation was 6.0 μm, and the relative standard deviation was 34%.

### Example 15

225 parts by mass of solder particles was mixed into 118 parts by mass of binder to prepare an anisotropic conductive film having a thickness of 40 μm, which was then cut to a width of 0.6 mm and a length of 8 mm. Anisotropic conductive films having a width of 0.6 mm were temporarily pasted on the first terminal row to fourth terminal row. As illustrated in Table 4, the sample of Example 15 had an evaluation of bridge occurrence of OK, the average value of solder height was 26.3 μm, the standard deviation was 4.4 μm, and the relative standard deviation was 17%.

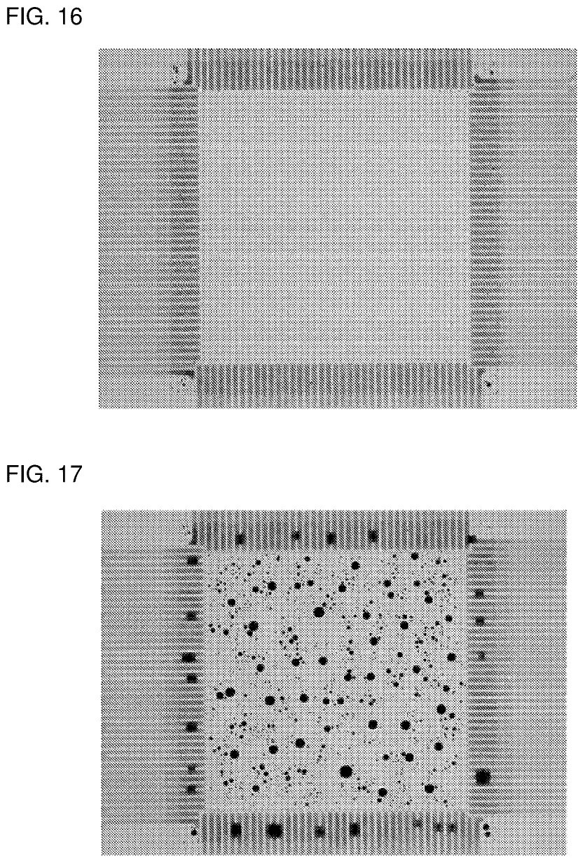

FIG. 16 is an X-ray photograph showing a sample after reflow for Example 15. The photograph in FIG. 16 shows that there is no residual solder in the gap and that a solder joint without bridging has been formed.

### Comparative Example 8

225 parts by mass of solder particles was mixed into 118 parts by mass of binder to prepare an anisotropic conductive film having a thickness of 40 μm, which was then cut to a width of 9.2 mm and a length of 9.2 mm. The anisotropic conductive film of 9.2 mm×9.2 mm was temporarily bonded on the entire surface, including the first terminal row to the fourth terminal row. As illustrated in Table 4, the sample of Comparative Example 8 had an evaluation of bridge occurrence of NG, the average value of solder height was 28.1 μm, the standard deviation was 16.1 μm, and the relative standard deviation was 57%.

FIG. 17 is an X-ray photograph showing a sample after reflow for Comparative Example 8. The photograph in FIG. 17 shows that there is residual solder in the gap and that a solder joint with bridging has been formed.

TABLE 4

| | | Example | Comparative | Example | Comparative |
|---|---|---|---|---|---|
| | | 14 | Example 7 | 15 | Example 8 |
| Binder [parts by weight] | | 118 | | 118 | |
| Solder particles [parts by mass] | | 204 | | 225 | |
| Total [parts by mass] | | 322 | | 343 | |
| Particle amount [vol %] | | 20 | | 23 | |
| Film thickness [μm] | | 40 | | 40 | |
| How to apply | | 4-row pasting | Full surface pasting | 4-row pasting | Full surface pasting |
| Film width [mm] | | 0.6 | 9.2 | 0.6 | 9.2 |
| Evaluation of bridging occurrence | | OK | NG | OK | NG |
| Solder | Ave [μm] | 23.5 | 17.7 | 26.3 | 28.1 |
| height | σ [μm] | 4.0 | 6.0 | 4.4 | 16.1 |
| | RSD [%] | 17 | 34 | 17 | 57 |

In Comparative Examples 7 and 8, an anisotropic conductive film was temporarily bonded on the entire surface including the first terminal row to fourth terminal row, a bridge occurred, and the standard deviation and the relative standard deviation of the solder height were high. This is thought to be because the solder particles move between the first terminal row and second terminal row, making it inefficient for the solder particles to aggregate on the terminals.

Conversely, in Examples 14 and 15, the anisotropic conductive films are temporarily bonded to the first terminal row to fourth terminal row, respectively, no bridge occurred, and standard deviation and relative standard deviation of solder height are low.

### 6. Fourth Example

In a fourth example, a connection structure was prepared using an anisotropic conductive film of a predetermined shape, and solder residue in which solder particles were present outside the terminal portions was observed and evaluated using X-ray photographs.

### [Preparation of Anisotropic Conductive Film]

A binder was prepared by blending 45 parts by mass of phenoxy resin (YP-50, Nippon Steel Chemical & Material Co., Ltd.), 10 parts by mass of hydrogenated bisphenol A glycidyl ether (YX8000, Mitsubishi Chemical Corporation), 45 parts by mass of crystalline bisphenol A epoxy resin (YL6810, Mitsubishi Chemical Corporation), 10 parts by mass of an imidazole-based epoxy resin curing agent (2P4MHZ-PW (2-phenyl-4-methyl-5-hydroxymethylimidazole), Shikoku Chemical Industry Co., Ltd.), and 8 parts by mass of glutaric acid (1,3-propanedicarboxylic acid, Tokyo Chemical Industry Co., Ltd.). 300 parts by mass of solder particles (Sn59.9Bi40Cu0.1) having an average particle diameter of 20 μm was added (28 Vol %) to 118 parts by mass of a binder to produce an anisotropic conductive film having a thickness of 30 μm.

### [Preparation of Connection Structure]

### (Plug Connector Structure)

A wiring board for a plug connector (first terminal row and second terminal row formed in parallel, with a pair of electrodes formed at both ends of the first terminal row and second terminal row at a distance smaller than the distance between the first terminal row and second terminal row; the distance between the first terminal row and second terminal row was 0.8 mm; the first terminal row and second terminal row had a 0.35 mm pitch (line/space=0.18/0.17 mm, terminal length 0.8 mm), a glass epoxy substrate thickness of 1.5 mm, a copper pattern thickness of 18 μm, and a surface OSP treatment) was prepared as the substrate.

A plug connector (10 pins on one side (20 pins on both sides of the terminal row), 0.35 mmP, line/space=0.12/0.23 mm, 2 pins on both sides+1 pin, terminal surface Au plating) was prepared as the connector.

### (Receptacle Connector Structure)

A wiring board for a receptacle connector (first terminal row and second terminal row formed in parallel, with an electrode spanning both ends of the first terminal row and second terminal row; the distance between the first terminal row and second terminal row was 0.8 mm; the first terminal row and second terminal row had a 0.35 mm pitch (line/space=0.18/0.17 mm, terminal length 0.8 mm), a glass epoxy substrate thickness of 1.5 mm, a copper pattern thickness of 18 μm, and a surface OSP treatment) was prepared as the substrate.

A receptacle connector (10 pins on one side (20 pins on both sides), 0.35 mmP, line/space=0.12/0.23 mm, 2 pins on both sides+1 pin, terminal surface Au plating) was prepared as the connector.

The anisotropic conductive film was cut to a predetermined shape and temporarily pressed onto the terminals of the substrate under conditions of 45° C., 1 MPa, and 1 second to temporarily bond the anisotropic conductive film onto the terminals of the substrate. Next, a connector (plug connector or receptacle connector) was placed on the anisotropic conductive film of the predetermined shape, and reflow was carried out under the following reflow conditions to prepare a connection structure.

Reflow conditions: 150° C. to 250° C. for 100 seconds, peak top set at 250° C., heating rate 3.0° C./second

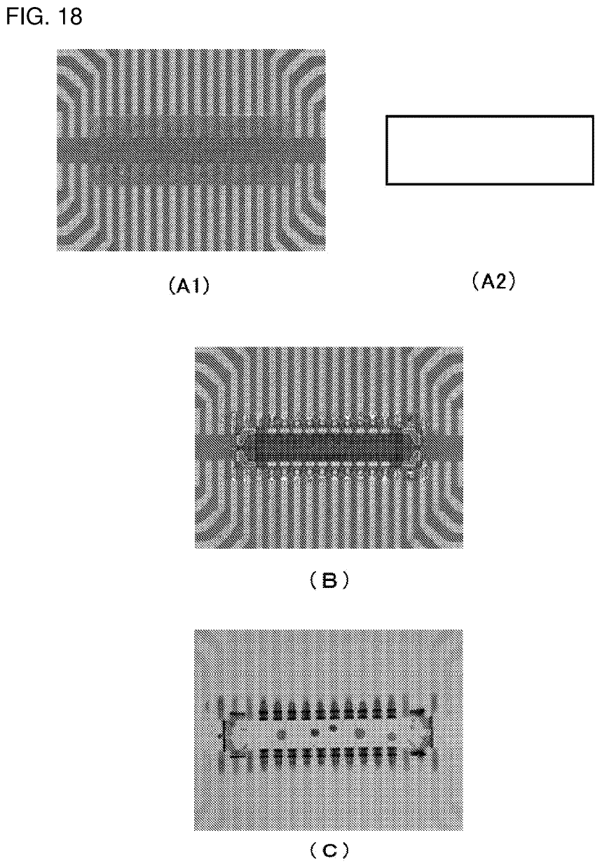

FIG. 18(A1) is a photograph showing a state in which an anisotropic conductive film of a predetermined shape has been temporarily pasted on a wiring board for a plug connector as Comparative Example 9, FIG. 18(A2) is a plan view schematically illustrating the shape of the anisotropic conductive film, FIG. 18(B) is a photograph showing a state in which a plug connector has been reflow mounted on a wiring board for a plug connector, and FIG. 18(C) is an X-ray photograph showing a plug connector structure after mounting.

As illustrated in FIG. 18(A1) to FIG. 18(C), in Comparative Example 9, a rectangular anisotropic conductive film was temporarily bonded on the entire surface including the first terminal row, the second terminal row, and the pair of electrodes at both ends, and then a plug connector was mounted. As illustrated in FIG. 18(A1) and FIG. 18(A2), when an anisotropic conductive film having no gap between the first terminal row and second terminal row was used, residual solder was observed between the first terminal row and second terminal row in the X-ray photograph illustrated in FIG. 18(C), and solder joints having bridges larger than the terminal width were also observed.

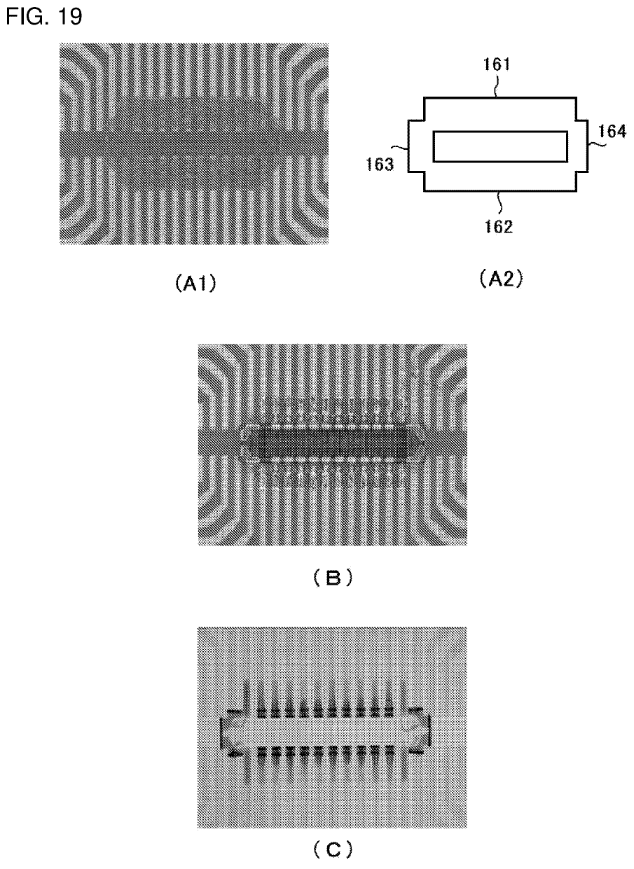

FIG. 19(A1) is a photograph showing a state in which an anisotropic conductive film of a predetermined shape has been temporarily bonded on a wiring board for a plug connector as Comparative Example 16, FIG. 19(A2) is a plan view schematically illustrating the shape of the anisotropic conductive film, FIG. 19(B) is a photograph showing a state in which a plug connector has been reflow mounted on a wiring board for a plug connector, and FIG. 19(C) is an X-ray photograph showing a plug connector structure after mounting.

As illustrated in FIG. 19(A1) to FIG. 19(C), in Example 16, an anisotropic conductive film having a substantially rectangular first shaped portion 161 corresponding to the first terminal row, a substantially rectangular second shaped portion 162 corresponding to the second terminal row, a third shaped portion 163 connecting one end of the first shaped portion 161 with one end of the second shaped portion 162 and to which one longitudinal end of the plug connector is bonded, and a fourth shaped portion 164 connecting the other end of the first shaped portion with the other end of the second shaped portion and to which the other longitudinal end of the plug connector is bonded was temporarily pasted, and the plug connector was mounted.

As illustrated in FIG. 19(A1) and FIG. 19(A2), when an anisotropic conductive film having a gap between the first terminal row and the second terminal row was used, the amount of solder residue was dramatically improved compared to Comparative Example 9, and substantially no solder residue was observed in the X-ray photograph illustrated in FIG. 19(C).

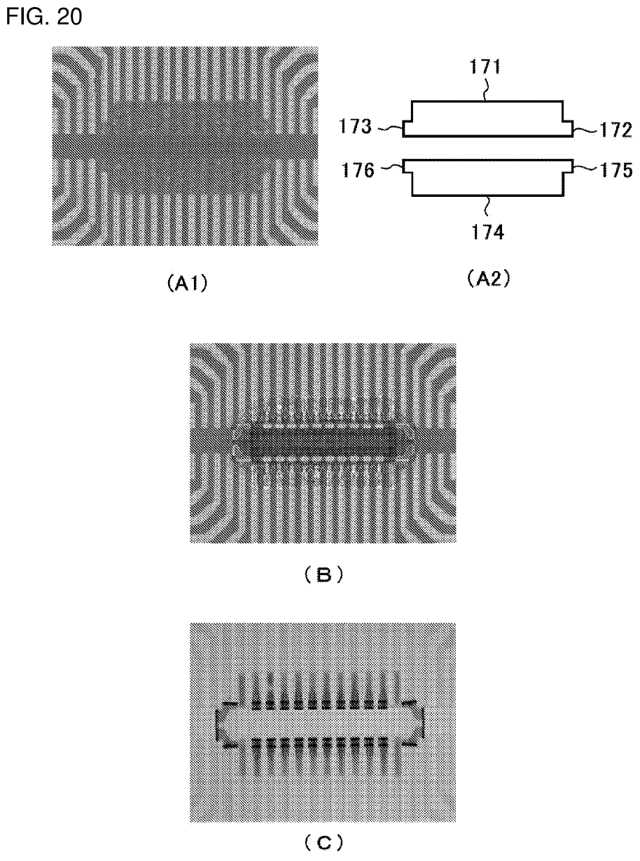

FIG. 20(A1) is a photograph showing a state in which an anisotropic conductive film of a predetermined shape has been temporarily bonded on a wiring board for a plug connector as Example 17, FIG. 20(A2) is a plan view schematically illustrating the shape of the anisotropic conductive film, FIG. 20(B) is a photograph showing a state in which a plug connector has been reflow mounted on a wiring board for a plug connector, and FIG. 20(C) is an X-ray photograph showing a plug connector structure after mounting.

As illustrated in FIG. 20(A1) to FIG. 20(C), in Example 17, a first anisotropic conductive film was temporarily bonded, having a substantially rectangular first shaped portion 171 corresponding to the first terminal row, a second shaped portion 172 that is continuous with one longitudinal end of the first shaped portion 171 and to which one longitudinal end of the plug connector is bonded, and a third shaped portion 173 that is continuous with the other longitudinal end of the first shaped portion 171 and to which the other longitudinal end of the plug connector is bonded, and a second anisotropic conductive film was temporarily bonded, having a substantially rectangular fourth shaped portion 174 corresponding to the second terminal row, a fifth shaped portion 175 that is continuous with one longitudinal end of the fourth shaped portion 174 and to which one longitudinal end of the plug connector is bonded, and a sixth shaped portion 176 that is continuous with the other longitudinal end of the fourth shaped portion 174 and to which the other longitudinal end of the plug connector is bonded, and the plug connector was mounted. In the state in which the first anisotropic conductive film and the second anisotropic conductive film are temporarily bonded, the distances between the first shaped portion 171 to the third shaped portion 173 and the distances between the fourth shaped portion 174 to the sixth shaped portion 176 are substantially the same.

As shown in FIG. 20(A1) and FIG. 20(A2), a first anisotropic conductive film and a second anisotropic conductive film shaped to bond both longitudinal ends of the plug connector were used, and a gap was provided between the first anisotropic conductive film and the second anisotropic conductive film, and as a result, substantially no solder residue was observed in the X-ray photograph illustrated in FIG. 20 (C), and in particular, solder residue at both longitudinal ends of the plug connector was improved.

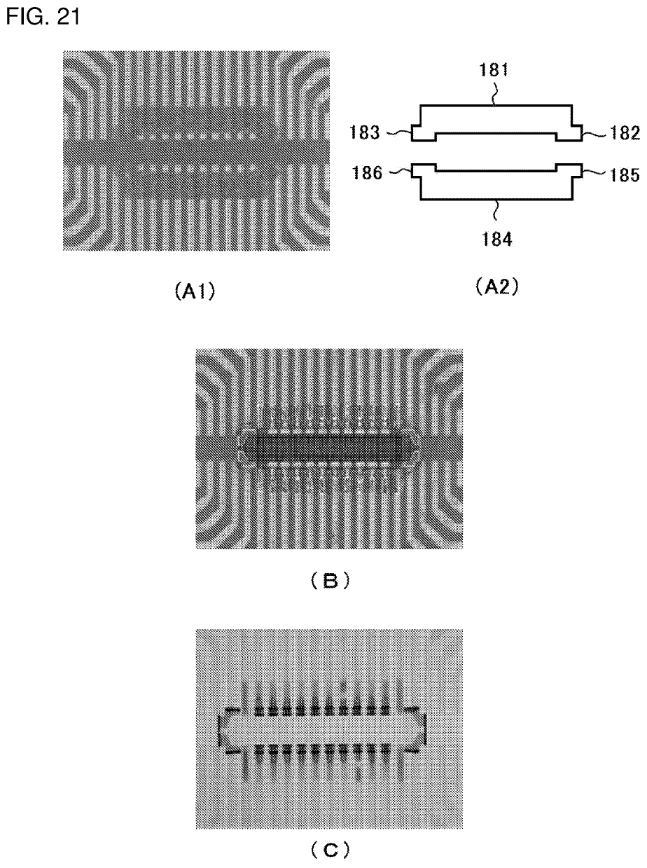

FIG. 21(A1) is a photograph showing a state in which an anisotropic conductive film of a predetermined shape has been temporarily bonded on a wiring board for a plug connector as Comparative Example 18, FIG. 21(A2) is a plan view schematically illustrating the shape of the anisotropic conductive film, FIG. 21(B) is a photograph showing a state in which a plug connector has been reflow mounted on a wiring board for a plug connector, and FIG. 21(C) is an X-ray photograph showing a plug connector structure after mounting.

As illustrated in FIG. 21(A1) to FIG. 21(C), in Example 18, a first anisotropic conductive film was temporarily bonded, having a substantially rectangular first shaped portion 181 corresponding to the first terminal row, a second shaped portion 182 that is continuous with one longitudinal end of the first shaped portion 181 and to which one longitudinal end of the plug connector is bonded, and a third shaped portion 183 that is continuous with the other longitudinal end of the first shaped portion 181 and to which the other longitudinal end of the plug connector is bonded, and a second anisotropic conductive film was temporarily bonded, having a substantially rectangular fourth shaped portion 184 corresponding to the second terminal row, a fifth shaped portion 185 that is continuous with one longitudinal end of the fourth shaped portion 184 and to which one longitudinal end of the plug connector is bonded, and a sixth shaped portion 186 that is continuous with the other longitudinal end of the fourth shaped portion 184 and to which the other longitudinal end of the plug connector is bonded, and the plug connector was mounted. When the first anisotropic conductive film and the second anisotropic conductive film are temporarily bonded, the distance between the first shaped portion 181 and the fourth shaped portion 184 is greater than the distance between the second shaped portion 182 and the fifth shaped portion 185 and the distance between the third shaped portion 183 and the sixth shaped portion 186.

As shown in FIG. 21(A1) and FIG. 21(A2), a first anisotropic conductive film and a second anisotropic conductive film shaped to bond both longitudinal ends of the plug connector were used, and the gap distance between the first shaped portion 181 and the fourth shaped portion 184 was made larger than in Example 17. As a result, substantially no solder residue was observed in the X-ray photograph illustrated in FIG. 21 (C), and in particular, the solder residue in the first terminal row and the second terminal row was improved.

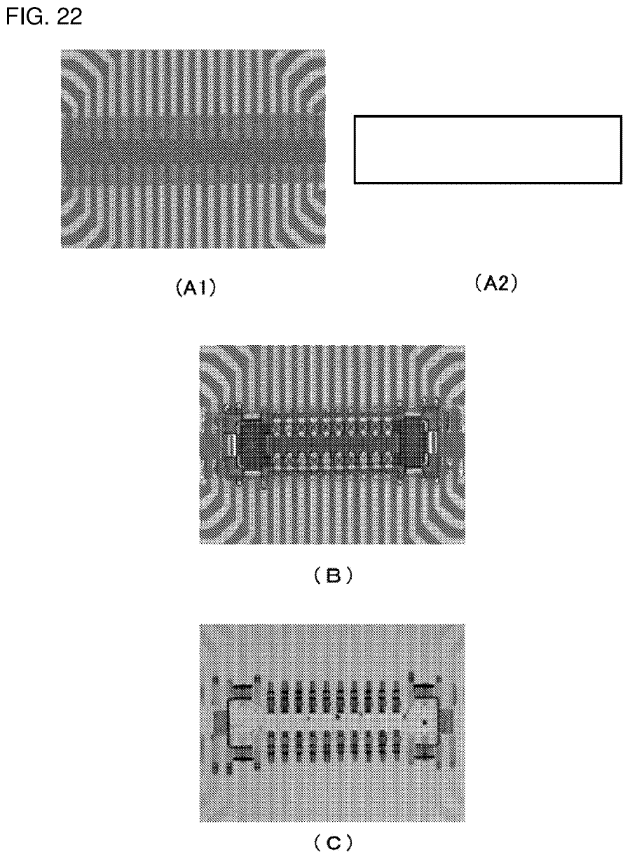

FIG. 22(A1) is a photograph showing a state in which an anisotropic conductive film of a predetermined shape is temporarily bonded to a wiring board for a receptacle connector as Comparative Example 10, FIG. 22(A2) is a plan view schematically illustrating the shape of the anisotropic conductive film, FIG. 22(B) is a photograph showing a state in which the receptacle connector is reflow mounted on the wiring board for the receptacle connector, and FIG. 22(C) is an X-ray photograph showing a receptacle connector structure after mounting.

As illustrated in FIG. 22(A1) to FIG. 22(C), in Comparative Example 10, a rectangular anisotropic conductive film was temporarily bonded on the entire surface of the receptacle connector, including both longitudinal ends, and the receptacle connector was mounted. As illustrated in FIG. 22(A1) and FIG. 22(A2), when an anisotropic conductive film having no gap between the first terminal row and second terminal row was used, residual solder was observed between the first terminal row and second terminal row in the X-ray photograph illustrated in FIG. 22(C), and solder joints having bridges larger than the terminal width were also observed.

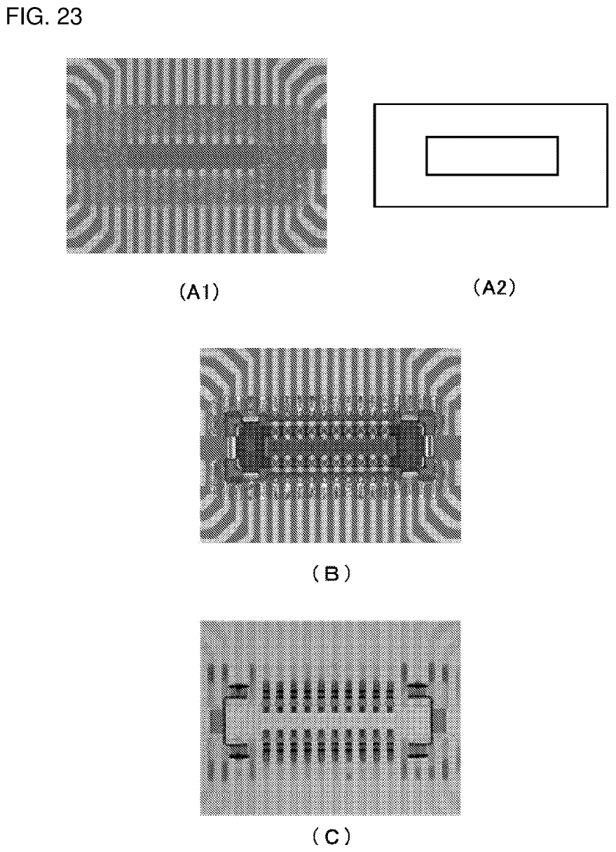

FIG. 23(A1) is a photograph showing a state in which an anisotropic conductive film of a predetermined shape is temporarily bonded to a wiring board for a receptacle connector as Comparative Example 19, FIG. 23(A2) is a plan view schematically illustrating the shape of the anisotropic conductive film, FIG. 23(B) is a photograph showing a state in which the receptacle connector is reflow mounted on the wiring board for the receptacle connector, and FIG. 23(C) is an X-ray photograph showing a receptacle connector structure after mounting.

As illustrated in FIG. 23(A1) to FIG. 23(C), in Example 19, an anisotropic conductive film having a rectangular gap having a width greater than the distance between the first terminal row and the second terminal row and the length of the terminal row portion of the receptacle connector was temporarily bonded on the center of a rectangle including both longitudinal ends of the receptacle connector, and the receptacle connector was mounted.

As illustrated in FIG. 23(A1) and FIG. 23(A2), when an anisotropic conductive film having a gap between the first terminal row and the second terminal row was used, the amount of solder residue was dramatically improved compared to Comparative Example 10, and substantially no solder residue was observed in the X-ray photograph illustrated in FIG. 23(C).

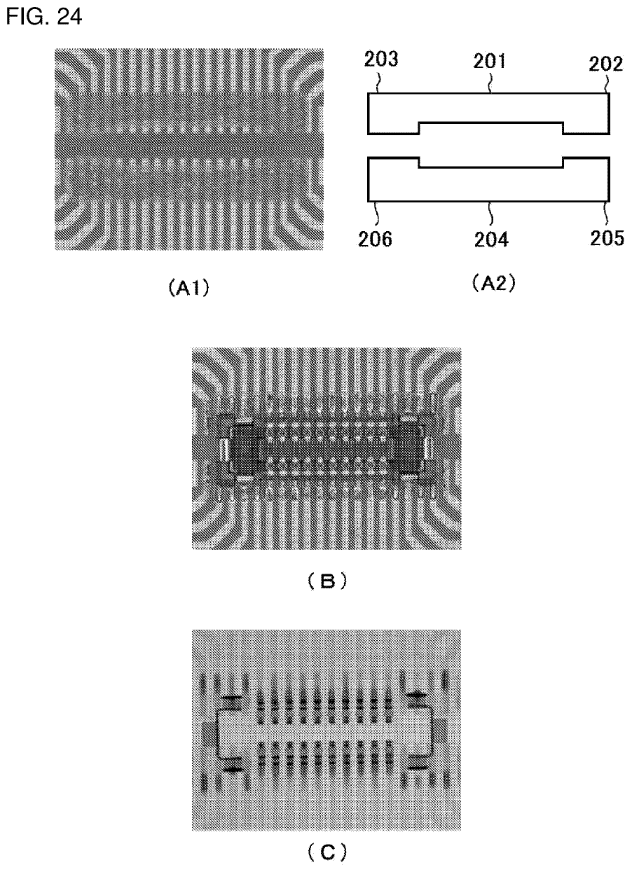

FIG. 24(A1) is a photograph showing a state in which an anisotropic conductive film of a predetermined shape is temporarily bonded to a wiring board for a receptacle connector as Comparative Example 20, FIG. 24(A2) is a plan view schematically illustrating the shape of the anisotropic conductive film, FIG. 24(B) is a photograph showing a state in which the receptacle connector is reflow mounted on the wiring board for the receptacle connector, and FIG. 24(C) is an X-ray photograph showing a receptacle connector structure after mounting.

As illustrated in FIG. 24(A1) to FIG. 24(C), in Example 20, a first anisotropic conductive film was temporarily bonded, having a substantially rectangular first shaped portion 201 corresponding to the first terminal row, a second shaped portion 202 that is continuous with one longitudinal end of the first shaped portion 201 and to which one longitudinal end of the receptacle connector is bonded, and a third shaped portion 203 that is continuous with the other longitudinal end of the first shaped portion 201 and to which the other longitudinal end of the receptacle connector is bonded. Furthermore, a second anisotropic conductive film was temporarily bonded, having a substantially rectangular fourth shaped portion 204 corresponding to the second terminal row, a fifth shaped portion 205 that is continuous with one longitudinal end of the fourth shaped portion 204 and to which one longitudinal end of the receptacle connector is bonded, a sixth shaped portion 206 that is continuous with the other end of the fourth shaped portion 204 and to which the other longitudinal end of the receptacle connector is bonded, and the receptacle connector was mounted. When the first anisotropic conductive film and the second anisotropic conductive film are temporarily bonded, the distance between the first shaped portion 201 and the fourth shaped portion 204 is greater than the distance between the second shaped portion 202 and the fifth shaped portion 205 and the distance between the third shaped portion 203 and the sixth shaped portion 206.

As shown in FIG. 24(A1) and FIG. 24(A2), a first anisotropic conductive film and a second anisotropic conductive film shaped to bond both longitudinal ends of the receptacle connector were used, and a gap was provided between the first anisotropic conductive film and the second anisotropic conductive film, and as a result, substantially no solder residue was observed in the X-ray photograph illustrated in FIG. 24(C), and in particular, solder residue at both longitudinal ends of the receptacle connector was improved.

### DESCRIPTION OF REFERENCE NUMERALS

10 wiring board, 11 first terminal row, 11a terminal, 12 second terminal row, 12a terminal, 20 solder particles, 21 first solder connection film, 22 second solder connection film, 30 surface mount device, 31 first terminal row, 32 second terminal row, 40 binder, 41 solder, 50 wiring board, 51 first terminal row, 51a to 51d terminals, 52 second terminal row, 52a to 52d terminals, 53 metal mask, 54 first opening, 55 second opening, 556 first solder paste film, 57 second solder paste film, 58 metal mask, 59 opening, 60 solder paste film, 61 metal mask, 62a to 62d openings, 63a to 63d openings, 64a to 64d solder paste films, 65a to 65d solder paste films, 70 receptacle, 71A, 71B receptacle terminals, 80 plug, 81A, 81B plug terminals, 82A, 82B connection pins, 83 insulating resin, 90 wiring board, 91A, 91B board terminals, 100 adhesive layer, 101 solder, 102 binder hardened product

1: A connection structure production method, comprising:
disposing a surface mount device comprising a plurality of terminal rows on a wiring board, interposing a film-shaped solder connection material having rectangular portions corresponding to each of the terminal rows; and
joining the surface mount device to the wiring board.

2: The connection structure production method according to claim 1, wherein a relative standard deviation of a solder thickness between a terminal of the surface mount device and a terminal of the wiring board after the joining is less than 25%.

3: The connection structure production method according to claim 1, wherein:
the surface mount device comprises a first terminal row and a second terminal row disposed in parallel;
disposing comprises disposing a first film-shaped solder connection material corresponding to the first terminal row and a second film-shaped solder connection material corresponding to the second terminal row; and
a distance between a rectangular portion of the first film-shaped solder connection material and a rectangular portion of the second film-shaped solder connection material is set to 0 mm or more.

4: The connection structure production method according to claim 3, wherein:
in the disposing, a width W of the rectangular portion of the first film-shaped solder connecting material and a width W of the rectangular portion of the second film-shaped solder connecting material each satisfy formula (1):
W≤(2L+S)/2 (1)
wherein, in the formula (1), L is a length of the terminals in the first terminal row and the second terminal row, and S is a distance between the first terminal row and the second terminal row.

5: The connection structure production method according to claim 1, wherein joining comprises bonding the surface mount device to the wiring board without load by heating in a reflow furnace.

6: The connection structure production method according to claim 1, wherein a pitch of the terminal rows of the surface mount device and the wiring board is 0.1 mm to 0.4 mm.

7: The connection structure production method according to claim 1, wherein a content of solder particles in the film-shaped solder connection material is 10% by volume to 60% by volume when a terminal row pitch is 0.1 mm to 0.4 mm on the surface mount device and the wiring board.

8: The connection structure production method according to claim 1, wherein:
the surface mount device comprises a first terminal row and a second terminal row disposed in parallel;
disposing comprises disposing a first film-shaped solder connection material corresponding to the first terminal row and a second film-shaped solder connection material corresponding to the second terminal row;
an amount of protrusion of a rectangular portion of the first film-shaped solder connection material from the first terminal row in the width direction is 50% or less of a terminal length of the first terminal row; and
an amount of protrusion of a rectangular portion of the second film-shaped solder connection material from the second terminal row in the width direction is 50% or less of a terminal length of the second terminal row.

9: The connection structure production method according to claim 1, wherein:
the surface mount device comprises a first terminal row and a second terminal row disposed in parallel, and a third terminal row and a fourth terminal row disposed in parallel and perpendicular to the first terminal row and the second terminal row; and
an amount of protrusion in a width direction of a rectangular portion corresponding to each of the first terminal row, the second terminal row, the third terminal row, and the fourth terminal row from the terminal row is 50% or less of a terminal length of each of the corresponding first terminal row, second terminal row, third terminal row, and fourth terminal row.

10: A connection structure comprising:
a surface mount device comprising a plurality of terminal rows;
a wiring board; and a
cured film of a film-shaped solder connection material provided for each of the terminal rows, joining the surface mount device and the wiring board, and having rectangular portions corresponding to each of the terminal rows.

11: The connection structure according to claim 10, wherein a relative standard deviation of a solder thickness between terminals of the surface mount device and terminals of the wiring board is less than 25%.

12: The connection structure according to claim 10, wherein a pitch of the terminal rows of the surface mount device and the wiring board is 0.1 mm to 0.4 mm.

13: The connection structure according to claim 10, wherein:
the surface mount device comprises a first terminal row and a second terminal row disposed in parallel;
an amount of protrusion of a rectangular portion of a first film-shaped solder connection material from the first terminal row in the width direction is 50% or less of a terminal length of the first terminal row; and
an amount of protrusion of a rectangular portion of a second film-shaped solder connection material from the second terminal row in the width direction is 50% or less of a terminal length of the second terminal row.

14: The connection structure production method according to claim 10, wherein:
the surface mount device comprises a first terminal row and a second terminal row disposed in parallel, and a third terminal row and a fourth terminal row disposed in parallel, perpendicular to the first terminal row and the second terminal row; and
an amount of protrusion in a width direction of a rectangular portion corresponding to each of the first terminal row, the second terminal row, the third terminal row, and the fourth terminal row from the terminal row is 50% or less of a terminal length of each of the corresponding first terminal row, second terminal row, third terminal row, and fourth terminal row.
